(19) United States
(12) Patent Application Publication
(10) Pub. No.: US 2026/0150501 A1
(43) Pub. Date: May 28, 2026

(54) DISPLAY APPARATUS

(71) Applicant: LG Display Co., Ltd., Seoul (KR)

(72) Inventor: Hyoung-Su Kim, Paju-si (KR)

(73) Assignee: LG Display Co., Ltd., Seoul (KR)

(21) Appl. No.: 19/231,246

(22) Filed: Jun. 6, 2025

(30) Foreign Application Priority Data
Nov. 25, 2024 (KR) 10-2024-0169795

(51) Int. Cl. H10K 59/121; H10K 59/124; H10K 59/131; H10K 59/38; H10K 59/80

(52) U.S. Cl. CPC H10K 59/1213; H10K 59/124; H10K 59/131; H10K 59/38; H10K 59/873

(57) ABSTRACT

A display apparatus in some examples can include a substrate including a plurality of subpixels, a thin-film transistor disposed on the substrate, a buffer layer disposed on the thin-film transistor, a pixel electrode disposed on the buffer layer and having planarized upper and lower surfaces, an organic layer disposed on the pixel electrode, a common electrode disposed on the organic layer, an encapsulation layer disposed on the common electrode, and a metal pattern disposed between the buffer layer and the pixel electrode. The metal pattern overlaps at least a portion of the pixel electrode and has planarized upper and lower surfaces.

### CROSS-REFERENCE TO RELATED APPLICATION

This application claims priority to Korean Patent Application No. 10-2024-0169795, filed in the Republic of Korea on Nov. 25, 2024, which is hereby expressly incorporated by reference for all purposes as if fully set forth herein into the present application.

### BACKGROUND

### Field

The present disclosure relates to a display apparatus.

### Discussion of the Related Art

Display apparatuses are applied to various electronic devices such as televisions, mobile phones, laptops, and tablets. Display apparatuses include organic light-emitting displays (OLEDs), which self-emit light, and liquid crystal displays (LCDs), which require an external light source.

An organic light-emitting display can include a plurality of pixels. Each of the plurality of pixels can include a light-emitting device, a driving transistor that controls the amount of driving current supplied to the light-emitting device from a power line according to the voltage of a gate electrode, and a switching transistor that supplies a data voltage of a data line to the gate electrode of the driving transistor in response to a scan signal of a scan line.

The light-emitting device includes an anode, an organic light-emitting layer, and a cathode, where the organic light-emitting layer can be highly susceptible to oxygen and/or moisture. Accordingly, an encapsulation layer can be disposed on the light-emitting device to protect it from physical impact, oxygen, and/or moisture.

### SUMMARY OF THE DISCLOSURE

Embodiments of the present disclosure can provide a display apparatus capable of blocking or minimizing hydrogen inflow into the active layer from the encapsulation layer.

Embodiments of the present disclosure can provide a display apparatus having a metal coating layer capable of preventing or minimizing hydrogen conduction in the active layer.

Embodiments of the present disclosure can provide a display apparatus having a metal structure and a coating layer capable of preventing or minimizing color mixing between a plurality of subpixels.

Embodiments of the present disclosure provide an improved display apparatus which address the limitations and disadvantages associated with the related art.

The problems to be solved or addressed by embodiments of the present disclosure are not limited to those described above, and other problems not explicitly mentioned will be readily understood by those skilled in the art from the following description.

A display apparatus according to embodiments of the present disclosure can comprise: a substrate comprising a plurality of subpixels; a thin film transistor disposed on the substrate; a buffer layer disposed on the thin film transistor; a pixel electrode disposed on the buffer layer and having planarized upper and lower surfaces; an organic layer disposed on the pixel electrode; a common electrode disposed on the organic layer; an encapsulation layer disposed on the common electrode; and a metal pattern disposed between the buffer layer and the pixel electrode, overlapping at least a portion of the pixel electrode, and having planarized upper surface and lower surfaces.

A display apparatus according to embodiments of the present disclosure can comprise: a substrate comprising a subpixel and a driving wiring; a first insulating layer disposed on the substrate; a buffer layer disposed on the first insulating layer; a pixel electrode disposed on the buffer layer and having a planarized upper surface and a planarized lower surface; a first metal structure positioned on one side of the pixel electrode; and a second metal structure positioned on the opposite side of the pixel electrode. The first metal structure can comprise a first head part disposed beneath the first insulating layer and a first partition part integrally connected to the first head part and inserted into a hole in the first insulating layer and a groove formed on the lower surface of the buffer layer. The second metal structure can comprise a second head part disposed beneath the first insulating layer and a second partition part integrally connected to the second head part and inserted into a hole in the first insulating layer and a groove formed on the lower surface of the buffer layer.

According to embodiments of the present disclosure, a display apparatus capable of blocking or minimizing hydrogen inflow into the active layer from the encapsulation layer can be provided.

According to embodiments of the present disclosure, a display apparatus having a metal coating layer capable of preventing or minimizing hydrogen conduction in the active layer can be provided.

According to embodiments of the present disclosure, a display apparatus having a metal structure and a coating layer capable of preventing or minimizing color mixing between a plurality of subpixels can be provided.

According to embodiments of the present disclosure, since an additional process for forming a planarization layer and a bank is not needed, a display apparatus enabling process optimization can be provided.

The effects of embodiments of the present disclosure are not limited to those described above, and other effects not explicitly mentioned will be readily understood by those skilled in the art from the description of the claims.

### BRIEF DESCRIPTION OF THE DRAWINGS

The present disclosure will be more fully understood from the following detailed description and the accompanying drawings, which are provided for illustrative purposes only and are not intended to limit the scope of the present disclosure.

FIG. 1 illustrates a display apparatus according to embodiments of the present disclosure.

FIG. 2 illustrates a display panel according to embodiments of the present disclosure.

FIG. 3 is a plan view illustrating a portion of a plurality of subpixels in the display panel according to embodiments of the present disclosure.

FIG. 4 and FIG. 5 are cross-sectional views taken along A-A′ of FIG. 3 in the display panel according to embodiments of the present disclosure.

FIG. 6 is a cross-sectional view taken along B-B′ of FIG. 3 in the display panel according to embodiments of the present disclosure.

FIG. 7 to FIG. 15 are process cross-sectional views illustrating steps for forming the structures of FIG. 5 and FIG. 6 according to embodiments of the present disclosure.

FIG. 16 is a plan view illustrating a portion of a plurality of subpixels in the display panel according to embodiments of the present disclosure.

FIG. 17 is a cross-sectional view taken along line C-C′ of FIG. 16 in the display panel according to embodiments of the present disclosure.

FIG. 18 is a cross-sectional view taken along line D-D′ of FIG. 16 in the display panel according to embodiments of the present disclosure.

FIG. 19 is a cross-sectional view taken along line B-B′ of FIG. 3 or line D-D′ of FIG. 16 in the display panel according to embodiments of the present disclosure.

FIG. 20 illustrates a display apparatus according to embodiments of the present disclosure.

FIG. 21 is a cross-sectional view taken along line I-I′ of FIG. 20 in the display panel according to embodiments of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the present disclosure will be described in detail with reference to the accompanying drawings. All the components of each display apparatus according to embodiments of the present disclosure are operatively coupled and configured.

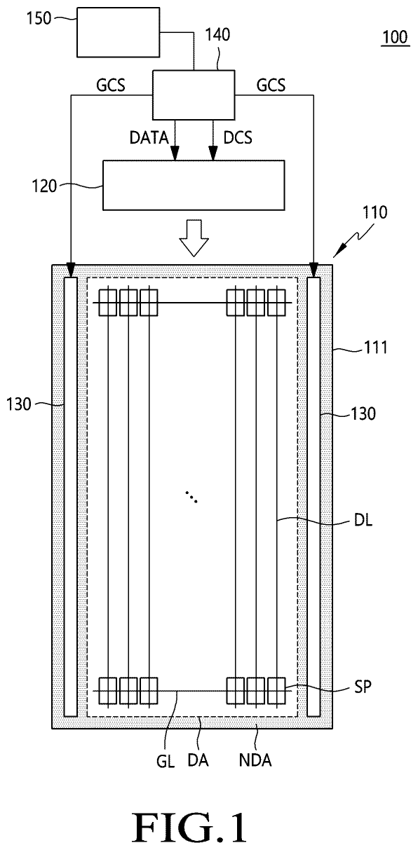

FIG. 1 is a system configuration diagram of a display apparatus 100 according to embodiments of the present disclosure.

Referring to FIG. 1, the display apparatus 100 according to embodiments of the present disclosure can include a display panel 110 and a display driving circuit as components for image display. The display driving circuit can be a circuit for driving the display panel 110. The display driving circuit can include a data driving circuit 120, a gate driving circuit 130, and a controller 140, but embodiments of the present disclosure are not limited thereto.

The display panel 110 can include a substrate 111 and a plurality of subpixels SP disposed on the substrate 111.

The substrate 111 can include a display area DA and a non-display area NDA.

The display area DA is an area capable of displaying images and can also be referred to as an active area. A plurality of subpixels SP for image display can be arranged in the display area DA. The non-display area NDA is an area where images are not displayed and can be an outer region of the display area DA. The non-display area NDA can also be referred to as a bezel (or bezel area) and can include a pad area (also referred to as a pad portion).

For example, the non-display area NDA can include a first non-display area surrounding the display area DA, a second non-display area that includes the pad area, and a bending area between the first and second non-display areas.

A driving circuit can be connected to, or bonded to, or attached to the pad area. Depending on the bending of the bending area, the bending area and the second non-display area can be positioned behind the first non-display area and thus may not be visible from the front. The first non-display area can have a very small size. Embodiments of the present disclosure are not limited thereto.

When a user views the display apparatus 100 from the front, the non-display area NDA that is visible to the user can be minimal or even nonexistent. However, embodiments of the present disclosure are not limited thereto.

The display apparatus 100 according to embodiments of the present disclosure can be a self-emitting display apparatus in which the display panel 110 self-emits light. However, embodiments of the present disclosure are not limited thereto. In the case where the display apparatus 100 according to embodiments of the present disclosure is a self-emitting display apparatus, each subpixel SP can include a light-emitting device.

For example, the display apparatus 100 according to embodiments of the present disclosure can be an organic light-emitting display apparatus in which the light-emitting device is implemented as an organic light-emitting diode (OLED). In another example, the display apparatus 100 according to embodiments of the present disclosure can be an inorganic light-emitting display apparatus, in which the light-emitting device is implemented as an inorganic light-emitting diode. In yet another example, the display apparatus 100 according to embodiments of the present disclosure can be a quantum dot display apparatus, where the light-emitting device is a quantum dot, which is a semiconductor crystal that self-emits light. Additionally, the display apparatus 100 according to embodiments of the present disclosure can be a micro-LED display apparatus or a mini-LED display apparatus.

Depending on the type of display apparatus 100, the structure of each subpixel SP can vary. For example, if the display apparatus 100 is a self-emitting display apparatus where the subpixels SP self-emit light, each subpixel SP can include a light-emitting device that self-emits light, at least one transistor, and at least one capacitor. However, embodiments of the present disclosure are not limited thereto.

Various types of signal lines for driving the plurality of subpixels SP can be arranged on the substrate 111 of the display panel 110. For example, these signal lines can include a plurality of data lines DL for transmitting data signals (also referred to as data voltages or image signals) to the plurality of subpixels SP, and a plurality of gate lines GL for transmitting gate signals (also referred to as scan signals) to the plurality of subpixels SP.

For example, the plurality of data lines DL and gate lines GL can intersect each other. Each of the plurality of gate lines GL can extend and be arranged in a first direction (e.g., a row direction or a column direction). Each of the plurality of data lines DL can extend and be arranged in a second direction different from the first direction (e.g., column direction or row direction).

In embodiments of the present disclosure, the angle formed between the first direction and the second direction can be perpendicular (90 degrees) or an angle other than 90 degrees.

The data driving circuit 120 can be a circuit for driving the plurality of data lines DL and can output data signals to the plurality of data lines DL.

The data driving circuit 120 can receive digital image data (DATA) from the controller 140, convert the received image data into analog data signals (also referred to as data voltages), and output the signals to the plurality of data lines DL.

In the display apparatus 100 according to embodiments of the present disclosure, the gate driving circuit 130 can be embedded in the display panel 110 as a Gate In Panel (GIP) type, but embodiments of the present disclosure are not limited thereto.

The gate driving circuit 130 can include a plurality of transistors. Each of the transistors included in the gate driving circuit 130 can include an active layer comprising a first semiconductor material, and each of the multiple transistors included in the subpixels SP can include an active layer comprising a second semiconductor material. In one example, the first semiconductor material and the second semiconductor material can be substantially identical. In another example, the first semiconductor material and the second semiconductor material can be different. For example, the first semiconductor material can be a silicon-based semiconductor material, such as low-temperature polycrystalline silicon (LTPS), while the second semiconductor material can be an oxide semiconductor material. In another example, the active layer can be a semiconductor layer, but embodiments of the present disclosure are not limited thereto.

The controller 140 is a device for controlling the data driving circuit 120 and the gate driving circuit 130, and it can control the driving timing of the plurality of data lines DL and gate lines GL.

The controller 140 can supply a data driving control signal DCS to the data driving circuit 120 to control it, and can supply a gate driving control signal GCS to the gate driving circuit 130 to control it.

The controller 140 can receive input image data from a host system 150 and supply image data (DATA) to the data driving circuit 120 based on the received input image data.

The display apparatus 100 according to embodiments of the present disclosure can be a mobile device, such as a smartphone or tablet, or a monitor or television (TV) of various sizes. However, embodiments of the present disclosure are not limited thereto and can be applied to various types and sizes of displays capable of displaying information or images.

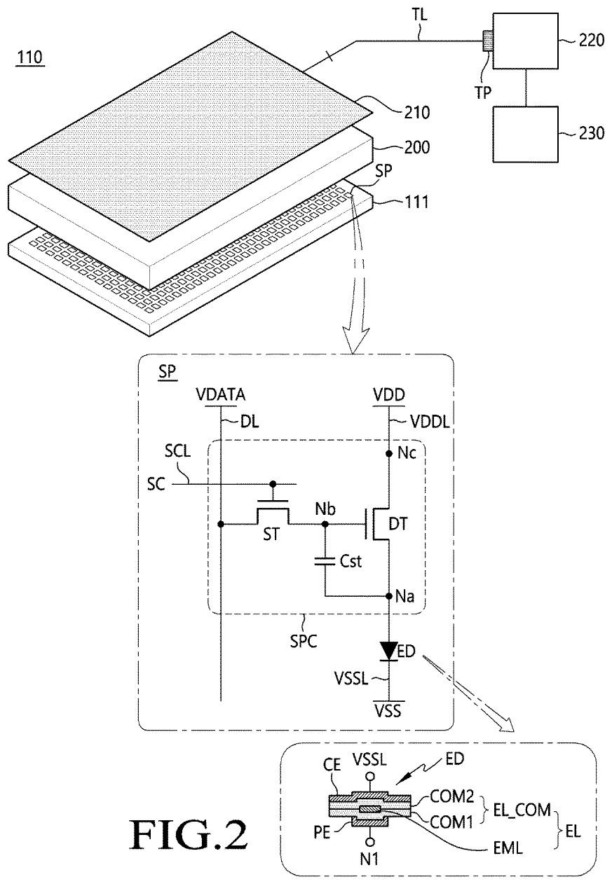

FIG. 2 illustrates the display apparatus 100 according to embodiments of the present disclosure.

Referring to FIG. 2, the display panel 110 according to embodiments of the present disclosure can include a substrate 111 on which a plurality of subpixels SP are disposed, and an encapsulation layer 200 on the substrate 111. The encapsulation layer 200 can also be referred to as an encapsulation substrate or an encapsulation part.

Referring to FIG. 2, when the display apparatus 100 according to embodiments of the present disclosure is a self-emitting display apparatus, each subpixel SP disposed on the substrate 111 can include a light-emitting device ED and a subpixel circuit SPC for driving the light-emitting device ED.

Referring to FIG. 2, the subpixel circuit SPC can include a plurality of transistors and at least one capacitor for driving the light-emitting device ED, but embodiments of the present disclosure are not limited thereto. In the present disclosure, the subpixel circuit SPC can drive the light-emitting device ED by supplying a driving current at a predetermined timing. The light-emitting device ED can be driven by the driving current to emit light.

The plurality of transistors can include a driving transistor DT for driving the light-emitting device ED and a scan transistor ST that is turned on or off in response to a scan signal SC.

The driving transistor DT can supply a driving current to the light-emitting device ED. The scan transistor ST can be configured to control the electrical state of a corresponding node in the subpixel circuit SPC or to control the state or operation of the driving transistor DT. At least one capacitor can include a storage capacitor Cst for maintaining a constant voltage during a frame.

For driving a subpixel SP, a data signal VDATA, which is an image signal, and a scan signal SC, which is a type of gate signal, can be applied to the subpixel SP. Additionally, for the driving of the subpixel SP, a common driving signal, including a driving voltage VDD and a reference voltage VSS, can be applied to the subpixel SP.

The light-emitting device ED can include a pixel electrode PE, an intermediate layer EL, and a common electrode CE. The intermediate layer EL can be disposed between the pixel electrode PE and the common electrode CE.

For example, the pixel electrode PE can be an electrode disposed within each subpixel SP, while the common electrode CE can be a shared electrode commonly disposed across multiple subpixels SP. In one example, the pixel electrode PE can be an anode, and the common electrode CE can be a cathode. In another example, the pixel electrode PE can be a cathode, and the common electrode CE can be an anode. Hereinafter, for ease of explanation, an example in which the pixel electrode PE is an anode and the common electrode CE is a cathode will be described.

When the light-emitting device ED is an organic light-emitting device, the intermediate layer EL can include a light-emitting layer EML, a first common intermediate layer COM1 between the pixel electrode PE and the light-emitting layer EML, and a second common intermediate layer COM2 between the light-emitting layer EML and the common electrode CE. The first common intermediate layer COM1 and the second common intermediate layer COM2 can be collectively referred to as the common intermediate layer EL_COM.

The light-emitting layer EML can be disposed in each subpixel SP or can be commonly disposed across multiple subpixels SP. The common intermediate layer EL_COM can be commonly disposed across multiple subpixels SP; however, embodiments of the present disclosure are not limited thereto.

For example, the light-emitting layer EML can be disposed in each light-emitting region or can be commonly disposed across multiple light-emitting regions. The common intermediate layer EL_COM can be commonly disposed across multiple light-emitting regions and non-light-emitting regions; however, embodiments of the present disclosure are not limited thereto.

For example, the first common intermediate layer COM1 can include a hole injection layer (HIL), an electron blocking layer (EBL), and a hole transport layer (HTL); however, embodiments of the present disclosure are not limited thereto. The second common intermediate layer COM2 can include an electron transport layer (ETL), a hole blocking layer (HBL), and an electron injection layer (EIL); however, embodiments of the present disclosure are not limited thereto.

For example, the common electrode CE can be electrically connected to a reference voltage line VSSL. A reference voltage VSS, which is a type of common voltage, can be applied to the common electrode CE via the reference voltage line VSSL. The pixel electrode PE can be electrically connected, either directly or indirectly (via another transistor), to a first node Na of the driving transistor DT in each subpixel SP. In the present disclosure, the reference voltage VSS can also be referred to as a first common voltage, a low-potential power supply voltage, or a low-potential voltage, and the reference voltage line VSSL can also be referred to as a first common voltage wiring, a low-potential power supply voltage line, or a low-potential voltage line.

Each light-emitting device ED can be composed of the overlapping portions of the pixel electrode PE, the light-emitting layer EML within the intermediate layer EL, and the common electrode CE. A predetermined light-emitting region can be formed by each light-emitting device ED. For example, the light-emitting region of each light-emitting device ED can include the overlapping areas of the pixel electrode PE, the light-emitting layer EML within the intermediate layer EL, and the common electrode CE.

For example, the light-emitting device ED can be an organic light-emitting diode (OLED: Organic Light-Emitting Diode), an inorganic light-emitting diode (LED: Light-Emitting Diode), a quantum dot light-emitting device, a micro-LED, or a mini-LED; however, embodiments of the present disclosure are not limited thereto. For example, when the light-emitting device ED is an organic light-emitting diode (OLED), the intermediate layer EL of the light-emitting device ED can include an organic material-containing intermediate layer EL.

The driving transistor DT can be a driving transistor for supplying a driving current to the light-emitting device ED. The driving transistor DT can be connected between the driving voltage line VDDL and the light-emitting device ED.

The driving transistor DT can include a first node Na, a second node Nb, and a third node Nc. The first node Na can be electrically connected to the light-emitting device ED, the second node Nb can have a data signal VDATA applied to it, and the third node Nc can have a driving voltage VDD, which is another type of common voltage, applied to it from the driving voltage line VDDL. The driving transistor DT can be connected between the first node Na and the third node Nc.

Hereinafter, for ease of explanation, an example will be provided where, in the driving transistor DT, the second node Nb is a gate node, the first node Na is a source node, and the third node Nc is a drain node. However, embodiments of the present disclosure are not limited thereto.

The scan transistor ST included in the subpixel circuit SPC illustrated in FIG. 2 can be a switching transistor for delivering the data signal (VDATA), which is an image signal, to the second node Nb, which is the gate node of the driving transistor DT.

The scan transistor ST can be controlled to turn on or off by a scan signal SC, which is a type of gate signal applied through a scan line SCL, which is a type of gate line GL. Through this, the scan transistor ST can control the electrical connection between the second node Nb of the driving transistor DT and the data line DL. The drain or source electrode of the scan transistor ST can be electrically connected to the data line DL, while the source or drain electrode of the scan transistor ST can be electrically connected to the second node Nb of the driving transistor DT. The gate electrode of the scan transistor ST can be electrically connected to the scan line SCL.

The storage capacitor Cst can be electrically connected between the first node Na and the second node Nb of the driving transistor DT. The storage capacitor Cst can include at least one capacitor electrode electrically connected to the first node Na of the driving transistor DT and corresponding to the first node Na of the driving transistor DT, and at least one capacitor electrode electrically connected to the second node Nb of the driving transistor DT and corresponding to the second node Nb of the driving transistor DT.

The display panel 110 can have a top-emission structure or a bottom-emission structure. When the display panel 110 has a top-emission structure, at least a portion of the subpixel circuit SPC can overlap at least a portion of the light-emitting device ED in the vertical direction. Accordingly, the area of the light-emitting region can increase, and the aperture ratio can improve. When the display panel 110 has a bottom-emission structure, the subpixel circuit SPC may not overlap the light-emitting device ED in the vertical direction.

As illustrated in FIG. 2, the subpixel circuit SPC can have a 2T1C (two-transistor, one-capacitor) structure that includes two transistors DT and ST and one capacitor Cst. In some cases, it can further include one or more additional transistors or one or more additional capacitors.

Since circuit elements in each subpixel SP (e.g., light-emitting devices (ED) implemented as organic light-emitting diodes (OLEDs) containing organic materials) are vulnerable to external moisture and oxygen, an encapsulation layer 200 can be disposed in the display panel 110. The encapsulation layer 200 can prevent external moisture or oxygen from penetrating the circuit elements (e.g., the light-emitting device ED). The encapsulation layer 200 can be configured in various forms to ensure that the light-emitting devices ED are not in contact with moisture or oxygen. For example, the encapsulation layer 200 can include two or more layers in which organic and inorganic films are alternately stacked. However, embodiments of the present disclosure are not limited thereto.

Referring to FIG. 2, the display apparatus 100 according to embodiments of the present disclosure can provide a touch-sensing function. To enable this functionality, it can include a touch sensor layer 210 in which a touch sensor is formed, and a touch sensing circuit for detecting the touch sensor formed in the touch sensor layer 210 to determine the presence of touch or touch coordinates. The touch sensor layer 210 can also be referred to as a touch part or a touch sensing part.

For example, the touch sensing circuit can include a touch driving circuit 220, which is configured to drive and sense the touch sensor formed in the touch sensor layer 210 to generate and output touch-sensing data, and a touch controller 230, which is configured to determine the presence of touch or touch coordinates using the touch sensing data provided by the touch driving circuit 220.

The touch sensor layer 210 is a layer in which a touch sensor is formed, and the touch sensor can be composed of a plurality of touch electrodes.

When the touch sensor layer 210 is embedded in the display panel 110, the display panel 110 can further include a plurality of touch pads TP to which the touch driving circuit 220 is electrically connected, in addition to the plurality of touch electrodes corresponding to the touch sensor. It can also include a plurality of touch routing wires TL that electrically connect the plurality of touch electrodes and the plurality of touch pads TP. The plurality of touch routing wires TL can also be referred to as multiple touch lines. Additionally, the plurality of touch routing wires TL can correspond to a plurality of touch channels.

The touch driving circuit 220 can supply a touch driving signal to at least one of the plurality of touch electrodes and sense at least one of the plurality of touch electrodes to generate touch-sensing data.

The touch sensing circuit can perform touch sensing using either a self-capacitance sensing method or a mutual-capacitance sensing method.

The display apparatus 100 can further include a power supply circuit that supplies various power sources to the display driving circuit and/or the touch sensing circuit. The power supply circuit can supply various voltages and power voltages related to display driving to the display driving circuit or the display panel 110.

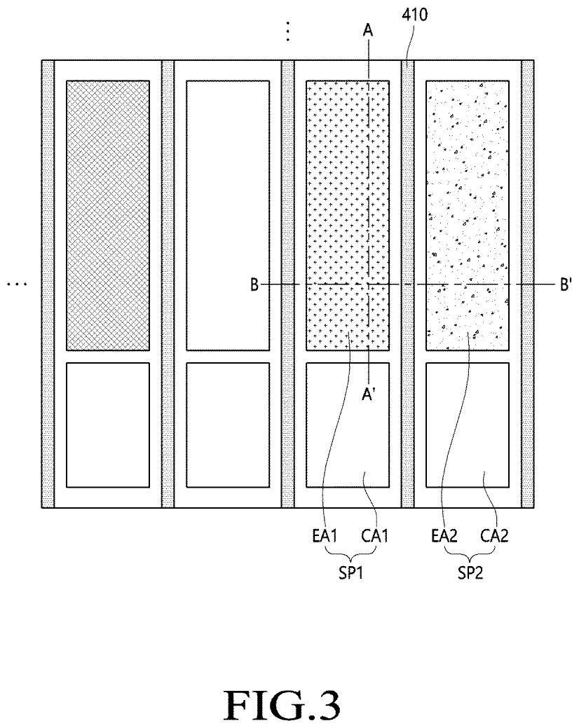

FIG. 3 is a plan view illustrating a portion of the plurality of subpixels in the display panel according to embodiments of the present disclosure.

Referring to FIG. 3, the plurality of subpixels can be arranged at regular intervals in the display area. The plurality of subpixels can include a first subpixel SP1 and a second subpixel SP2, which are arranged adjacent to each other.

The first subpixel SP1 and the second subpixel SP2 can emit different types of light through the driving of the transistor unit and the light-emitting device unit in the display panel. However, embodiments of the present disclosure are not limited thereto.

For example, the first subpixel SP1 can include a first light-emitting unit EA1 that emits blue (B) light, and the second subpixel SP2 can include a second light-emitting unit EA2 that emits green (G) light.

The first subpixel SP1 can further include a first circuit section CA1 in which a subpixel circuit for driving the light-emitting device of the first subpixel SP1 is disposed, and the second subpixel SP2 can further include a second circuit section CA2 in which a subpixel circuit for driving the light-emitting device of the second subpixel SP2 is disposed.

Referring to FIG. 3, since the first circuit section CA1 and the second circuit section CA2 do not overlap the first light-emitting unit EA1 and the second light-emitting unit EA2, respectively, the first subpixel SP1 and the second subpixel SP2 can have a bottom-emission structure.

Referring to FIG. 3, a driving signal wiring 410 can be disposed between the first subpixel SP1 and the second subpixel SP2. The driving signal wiring 410 can be disposed between the plurality of subpixels to supply power signals or image signals for driving to the adjacent subpixels.

For example, the driving signal wiring 410 can be a wiring for applying a driving voltage VDD, a data signal VDATA, and a reference voltage REF etc. to the subpixels.

In FIG. 3, line A-A′ is a cutting line extending from the first light-emitting unit EA1 of the first subpixel SP1 to the first circuit section CA1. Further, line B-B′ represents a cutting line extending from the first light-emitting unit EA1 of the first subpixel SP1 through the driving signal wiring 410 to the second light-emitting unit EA2 of the second subpixel SP2.

Hereinafter, the cross-sectional structure of the display panel along lines A-A′ and B-B′ according to embodiments of the present disclosure will be described in detail.

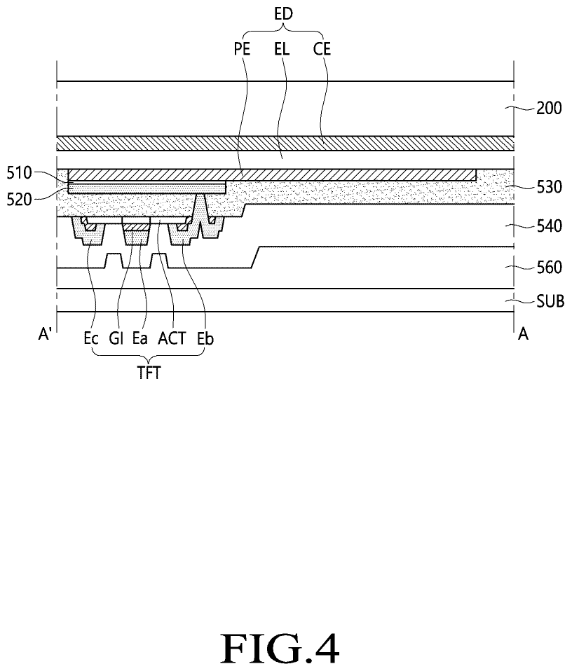

FIG. 4 is a cross-sectional view of the display panel along line A-A′ in FIG. 3 according to embodiments of the present disclosure.

Referring to FIG. 4, the display panel according to embodiments of the present disclosure can include a substrate SUB containing a plurality of subpixels, a thin-film transistor TFT disposed on the substrate SUB, a buffer layer 530 disposed on the thin-film transistor TFT, a pixel electrode PE disposed on the buffer layer 530 and having a planarized upper surface and a planarized lower surface, an organic layer EL disposed on the pixel electrode PE, a common electrode CE disposed on the organic layer EL, and an encapsulation layer 200 disposed on the common electrode CE.

The substrate SUB can correspond to the substrate 111 in FIG. 1. The substrate SUB can be a single-layer or multi-layer structure. When the substrate SUB is a multi-layer structure, it can include a first substrate, an intermediate substrate layer, and a second substrate. The intermediate substrate layer can be located between the first substrate and the second substrate. For example, the first substrate 301 and the second substrate 303 can each be a polyimide (PI) layer. However, embodiments of the present disclosure are not limited thereto. The intermediate substrate layer can be an inorganic insulating layer. However, embodiments of the present disclosure are not limited thereto. If the first substrate, which is a polyimide layer, accumulates charge, the intermediate substrate layer can prevent the charge from affecting the transistors disposed on the second substrate 303, which is also a polyimide layer, through the second substrate 303.

When the display apparatus according to embodiments of the present disclosure has a bottom-emission structure, the substrate SUB can include a transparent material such as glass, allowing light emitted from the light-emitting device ED to pass through the lower surface of the display panel. However, embodiments of the present disclosure are not limited thereto.

The thin-film transistor TFT can include a gate electrode Ea, a source electrode Eb, a drain electrode Ec, a gate insulating layer GI disposed on the gate electrode Ea, and an active layer ACT disposed on the gate insulating layer GI.

A light-emitting device ED can be disposed on the buffer layer 530, and the light-emitting device ED can include a pixel electrode PE, an organic layer EL, and a common electrode CE. The organic layer EL is a light-emitting layer containing organic material and can emit white (W) light. However, embodiments of the present disclosure are not limited thereto.

The encapsulation layer 200 can prevent moisture or oxygen from penetrating the light-emitting device ED. For example, the encapsulation layer 200 can prevent moisture or oxygen from penetrating the organic material contained in the intermediate layer EL of the light-emitting device ED. The encapsulation layer 200 can be configured as a single layer or multiple layers.

The display panel according to embodiments of the present disclosure can include a metal pattern 520 disposed between the buffer layer 530 and the pixel electrode PE, at least partially overlapping the pixel electrode PE, and having planarized upper and lower surfaces.

Since the metal pattern 520 is disposed beneath the pixel electrode PE having a planarized lower surface, it can have planarized upper and lower surfaces.

The metal pattern 520 can overlap the thin-film transistor TFT and may not overlap a portion of the pixel electrode PE.

The display panel according to embodiments of the present disclosure can further include a metal coating layer 510 disposed on the metal pattern 520 and having planarized upper and lower surfaces.

The metal coating layer 510 can be disposed between the metal pattern 520 and the pixel electrode PE. Since the metal coating layer 510 is disposed on the metal pattern 520 having a planarized upper surface, it can have planarized upper and lower surfaces.

For example, in the display panel according to embodiments of the present disclosure, the pixel electrode PE, the metal pattern 520, and the metal coating layer 510 can all have a flat structure.

The metal coating layer 510 can overlap the thin-film transistor TFT and may not overlap a portion of the pixel electrode PE.

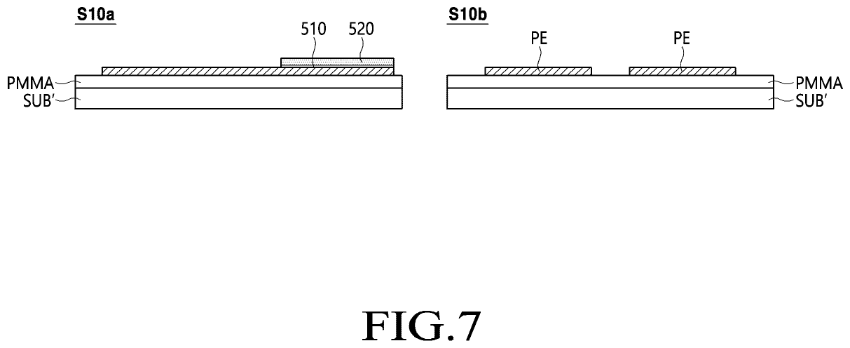

The structure of the thin-film transistor TFT, pixel electrode PE, metal pattern 520, and metal coating layer 510 described above is the result of the manufacturing process for forming the display panel according to embodiments of the present disclosure. The process steps will be explained with reference to FIG. 7 to FIG. 15.

Referring to FIG. 4, the display panel according to embodiments of the present disclosure can further include an adhesive layer 560 disposed on the substrate SUB and an insulating layer 540 disposed on the adhesive layer 560.

The adhesive layer 560 is made of resin and can be composed of one of epoxy, phenol, amino, unsaturated polyester, polyimide, silicone, acryl, vinyl, or olefin. The adhesive layer 560 can bond the laminated structure, including the thin-film transistor TFT, light-emitting device ED, encapsulation layer 200, and other components, to the substrate SUB, preventing separation. This bonding can be achieved through high-energy curing methods such as heat, ultraviolet (UV) light, or laser curing, or through the use of pressure-sensitive adhesive (PSA) that applies physical pressure. The adhesive layer 560 can include a transparent resin, allowing light emitted from the light-emitting device ED to pass through the lower surface of the display panel.

The insulating layer 540 is disposed between the substrate SUB and the thin-film transistor TFT and can partially overlap the buffer layer 530.

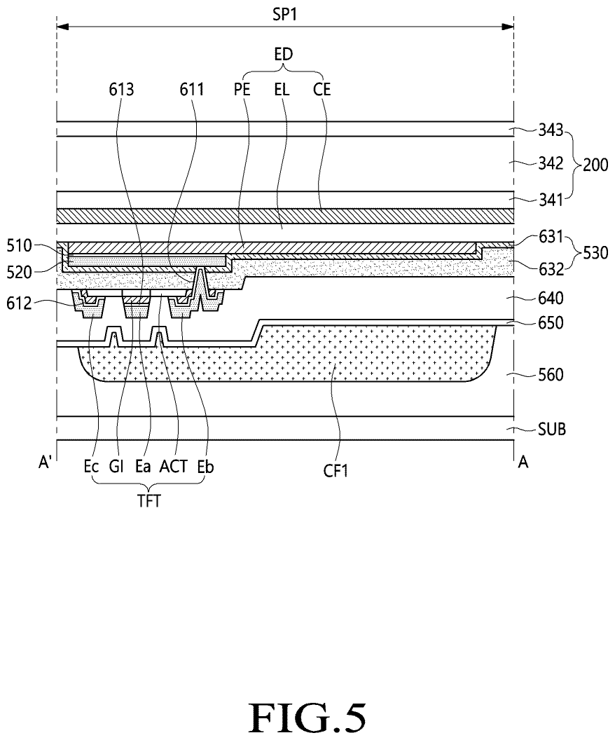

FIG. 5 is a cross-sectional view of the display panel according to embodiments of the present disclosure, taken along line A-A′ of FIG. 3.

Referring to FIG. 5, the display panel according to embodiments of the present disclosure can include a substrate SUB, an adhesive layer 560, a thin-film transistor TFT, a buffer layer, a metal pattern 520, a metal coating layer 510, a pixel electrode PE, an organic layer EL, a common electrode CE, and an encapsulation layer 200. Descriptions overlapping with FIG. 4 can be omitted.

The thin-film transistor TFT can include a gate electrode Ea, an active layer ACT disposed on the gate electrode Ea, a gate insulating layer GI disposed between the gate electrode Ea and the active layer ACT, a source electrode Eb connected to the lower surface of a portion of the active layer ACT, and a drain electrode Ec connected to the lower surface of another portion of the active layer ACT.

In the display panel according to embodiments of the present disclosure, the gate electrode Ea, source electrode Eb, and drain electrode Ec can include the same material as the metal pattern 520. However, embodiments of the present disclosure are not limited thereto.

In the display panel according to embodiments of the present disclosure, the active layer ACT can include an oxide semiconductor. For example, the active layer ACT can include indium tin oxide (ITO), indium zinc oxide (IZO), indium tin zinc oxide (ITZO), indium gallium zinc oxide (IGZO), or titanium nitride (TiN), but is not limited thereto.

The encapsulation layer 200 can include a first encapsulation layer 341, a second encapsulation layer 342 disposed on the first encapsulation layer 341, and a third encapsulation layer 343 disposed on the second encapsulation layer 342.

In the display panel according to embodiments of the present disclosure, at least one of the first encapsulation layer 341 and the third encapsulation layer 343 can include silicon nitride (SiNx).

In one example, the first encapsulation layer 341 can include silicon nitride, and the third encapsulation layer 343 can be an opaque thin-film metal substrate SUB (Face Seal Metal, FSM) composed of aluminum (Al), nickel (Ni), chromium (Cr), or an iron (Fe) and nickel alloy. In this case, the second encapsulation layer 342 is made of resin, which bonds the first encapsulation layer 341 and the third encapsulation layer 343 together, providing both encapsulation and planarization functions. Hereinafter, referred to as the “FSPM encapsulation structure.”

In another example, the first encapsulation layer 341 can include silicon nitride, and the third encapsulation layer 343 can include at least one of silicon nitride, silicon oxide (SiOx), or silicon oxynitride (SiOxNy). In this case, the second encapsulation layer 342 functions as a foreign material compensation layer and can include silicon oxycarbon (SiOCz), acryl, or epoxy-based resin. Hereinafter, referred to as the “TFE encapsulation structure.”

At least one of the first encapsulation layer 341 and the third encapsulation layer 343, which include silicon nitride, can contain a large amount of hydrogen internally. Hereinafter, the first encapsulation layer 341, which includes silicon nitride in the display panel according to embodiments of the present disclosure, will be described.

During the process of forming the display panel, when the first encapsulation layer 341 is deposited, special gases such as monosilane (SiH₄) and ammonia (NH₃), which contain a large amount of hydrogen, can be used. As a result, even after panel fabrication, the first encapsulation layer 341 can still contain a large amount of hydrogen internally.

A method exists for releasing the internally contained hydrogen through a high-temperature heat treatment process; however, the first encapsulation layer 341 may not undergo the dehydrogenation process through heat treatment. The first encapsulation layer 341 is formed to cover the light-emitting device ED, which is disposed on the thin-film transistor TFT after the active layer ACT has been deposited. Since the organic layer EL included in the light-emitting device ED is highly sensitive to high temperatures, it can be difficult to apply heat to the first encapsulation layer 341, which is formed on the light-emitting device ED.

Accordingly, the hydrogen contained inside the first encapsulation layer 341, which has not undergone dehydrogenation, can diffuse outward from the first encapsulation layer 341 in a gaseous or ionic state.

The hydrogen diffusing downward from the first encapsulation layer 341 can cause the active layer ACT, which includes an oxide semiconductor, to become conductive or significantly alter its conductivity. As a result, the electrical characteristics of the active layer ACT, such as electron mobility and resistance, can change.

In the display panel according to embodiments of the present disclosure, the active layer ACT can overlap the metal coating layer 510.

In the display panel according to embodiments of the present disclosure, the metal coating layer 510 can include a metal with excellent hydrogen absorption capability. For example, the metal coating layer 510 can include at least one of molybdenum (Mo), molybdenum titanium (MoTi), vanadium (V), niobium (Nb), tantalum (Ta), hafnium (Hf), zirconium (Zr), titanium (Ti), cerium (Ce), lanthanum (La), yttrium (Y), scandium (Sc), or lithium (Li), but is not limited thereto.

The metal included in the metal coating layer 510 can bond with hydrogen gas or ions diffusing from a silicon nitride layer, such as the first encapsulation layer 341. For example, by capturing the hydrogen diffusing from the first encapsulation layer 341, the metal coating layer 510 can prevent further diffusion of hydrogen into the active layer ACT. Accordingly, the metal coating layer 510 can prevent the the active layer ACT, which includes an oxide semiconductor, from becoming conductive, and can ensure the reliability of the thin-film transistor TFT by preventing changes in the electrical characteristics of the active layer ACT.

In the display panel according to embodiments of the present disclosure, a buffer layer can include a first buffer layer 631 and a second buffer layer 632, which is disposed beneath the first buffer layer 631. The first buffer layer 631 can be in contact with a portion of the lower surface of the organic layer EL and can be disposed to cover the lower surface of the pixel electrode PE and the metal pattern 520, and the side surface of the metal pattern layer 520.

In the display panel according to embodiments of the present disclosure, at least a portion of the first buffer layer 631 can overlap with the active layer ACT.

In the display panel according to embodiments of the present disclosure, the first buffer layer 631 and the second buffer layer 632 can include different inorganic materials. For example, the first buffer layer 631 can include silicon nitride, while the second buffer layer 632 can include silicon oxide.

When depositing the first buffer layer 631, which includes silicon nitride, during the manufacturing process of the display panel, the first buffer layer 631 can contain a large amount of hydrogen internally, as described above.

The process of forming the first buffer layer 631 can include a dehydrogenation process through heat treatment. For example, by performing a heat treatment process at a high temperature, hydrogen contained inside the first buffer layer 631 can be released to the exterior of the first buffer layer 631.

As will be described later, in the process of manufacturing the display panel according to embodiments of the present disclosure, the first buffer layer 631 can be formed before the deposition of the active layer ACT. Since the hydrogen content inside the first buffer layer 631 decreases after the dehydrogenation process, the amount of hydrogen diffusing from the first buffer layer 631 into the active layer ACT can be minimized.

In the display panel according to embodiments of the present disclosure, the first buffer layer 631 can have a sufficiently high density to bond with hydrogen gas or ions or to prevent their permeation. Accordingly, the first buffer layer 631 can block hydrogen diffusing from the first encapsulation layer 341 and the like, which also include different silicon nitride, from reaching the active layer ACT. Accordingly, the first buffer layer 631 can prevent the active layer ACT, which includes an oxide semiconductor, from becoming conductive, and ensure the reliability of the thin-film transistor TFT by preventing changes in the electrical characteristics of the active layer ACT.

Consequently, by arranging the metal coating layer 510 and the first buffer layer 631, which capture or block hydrogen diffusing from the first encapsulation layer 341 containing silicon nitride, it is possible to prevent the active layer ACT, which includes an oxide semiconductor, from undergoing hydrogen-induced conductivity.

Accordingly, in the display panel according to embodiments of the present disclosure, the hydrogen concentration of the first encapsulation layer 341 can be higher than that of the active layer ACT.

The display panel according to embodiments of the present disclosure can further include a first electrode coating layer 611 disposed on the source electrode Eb, a second electrode coating layer 612 disposed on the drain electrode Ec, and a third electrode coating layer 613 disposed on the gate electrode Ea.

The first to third electrode coating layers 611, 612 and 613 can include at least one of molybdenum (Mo), molybdenum-titanium (MoTi), vanadium (V), niobium (Nb), tantalum (Ta), hafnium (Hf), zirconium (Zr), titanium (Ti), cerium (Ce), lanthanum (La), yttrium (Y), scandium (Sc), and lithium (Li). For example, The first, second and third electrode coating layers 611, 612 and 613 can include the same material as the metal coating layer 510, but the present disclosure is not limited thereto.

In the display panel according to embodiments of the present disclosure, the source electrode Eb can be electrically connected to the lower surface of the metal pattern 520 through the first electrode coating layer 611. The source electrode Eb and the first electrode coating layer 611 can be electrically connected to the lower surface of the metal pattern 520, which is exposed through a contact hole penetrating the buffer layer.

The display panel according to embodiments of the present disclosure can further include a first color filter CF1 disposed between the substrate SUB and the thin-film transistor TFT, overlapping the pixel electrode PE, and corresponding to a first subpixel SP1 among a plurality of subpixels. For example, in the first subpixel SP1 that emits blue (B) light, the light emitted from the light-emitting device ED can pass through the first color filter CF1 and have a wavelength corresponding to blue (B) light.

When the display apparatus according to embodiments of the present disclosure has a bottom-emission structure, the common electrode CE can reflect the light emitted from the light-emitting device ED toward the lower surface of the display panel. For example, the common electrode CE can include a metal material with high reflectivity but is not limited thereto.

For example, the common electrode CE can include at least one of aluminum (Al) and a silver (Ag) alloy, wherein the silver (Ag) alloy can be an alloy of silver (Ag), palladium (Pd), and copper (Cu) etc.

In the display panel according to embodiments of the present disclosure, the metal coating layer 510 may not overlap with a portion of the pixel electrode PE that overlaps the light-emitting area of the first subpixel SP1. The light-emitting area of the first subpixel SP1, for example, the first emission region, can be an area where the pixel electrode PE does not overlap with the thin-film transistor TFT, and the first circuit region can be an area where the pixel electrode PE overlaps with the thin-film transistor TFT.

In other words, the metal coating layer 510 can overlap with the first circuit region and may not overlap with a portion of the first emission region.

Since the light emitted from the light-emitting device ED toward the lower surface can be reflected or scattered by the metal coating layer 510, which includes a metal with low light transmittance, it may not be emitted outside the display panel. Accordingly, the less the metal coating layer 510 overlaps with the first emission region, the higher the emission efficiency of the first subpixel SP1 can be.

The display panel according to embodiments of the present disclosure can further include a first insulating layer 640 disposed between the substrate SUB and the thin-film transistor TFT and a second insulating layer 650 disposed beneath the first insulating layer 640.

The first insulating layer 640 can be in contact with the lower surface of the thin-film transistor TFT and a portion of the lower surface of the second buffer layer 632.

In the display panel according to embodiments of the present disclosure, the first insulating layer 640 and the second insulating layer 650 can include silicon oxide but are not limited thereto.

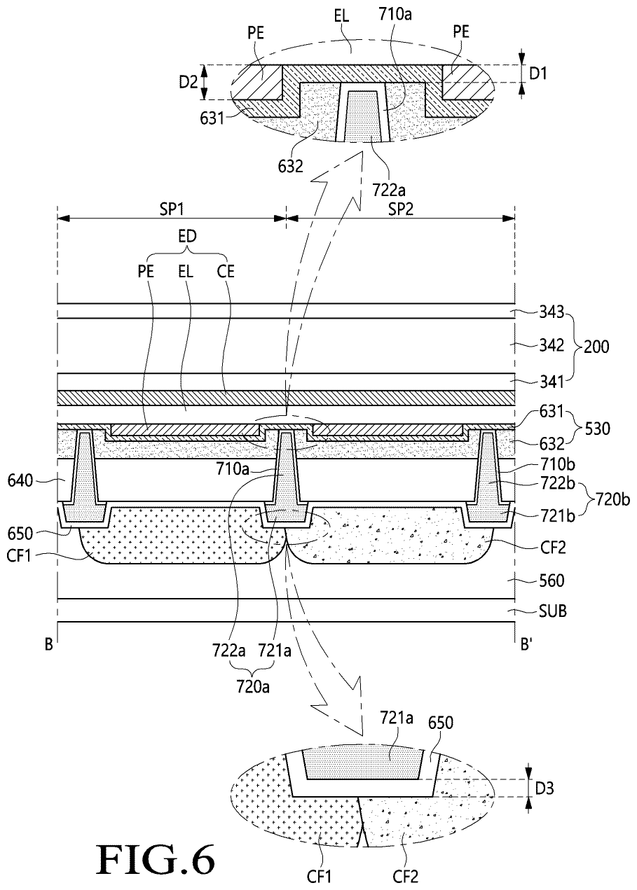

FIG. 6 is a cross-sectional view taken along B-B′ of FIG. 3 in the display panel according to embodiments of the present disclosure.

Referring to FIG. 6, the display panel according to embodiments of the present disclosure can include a substrate SUB comprising subpixels and driving signal wirings, a first insulating layer 640 disposed on the substrate SUB, a buffer layer disposed on the first insulating layer 640, and a pixel electrode PE disposed on the buffer layer, wherein the pixel electrode PE has a planarized upper surface and a planarized lower surface.

The display panel according to embodiments of the present disclosure can further include an adhesion layer 560, a second insulating layer 650, a first buffer layer 631, a second buffer layer 632, an organic layer EL, a common electrode CE, and first to third encapsulation layers 341, 342, and 343. Descriptions overlapping with the configurations of FIG. 4 and FIG. 5 can be omitted.

The display panel according to embodiments of the present disclosure can include a first metal structure 720a positioned on one side of the pixel electrode PE and a second metal structure 720b positioned on the opposite side of the pixel electrode PE.

The first metal structure 720a can include a first head part 721a disposed beneath the first insulating layer 640, and a first partition part 722a integrally connected to the first head part 721a, wherein the first partition part 722a is inserted into a hole of the first insulating layer 640 and a groove formed on the lower surface of the buffer layer 530. The second metal structure 720b can include a second head part 721b disposed beneath the first insulating layer 640, and a second partition part 722b integrally connected to the second head part 721b, wherein the second partition part 722b is inserted into a hole of the first insulating layer 640 and a groove formed on the lower surface of the buffer layer 530.

In the display panel according to embodiments of the present disclosure, the first metal structure 720a and the second metal structure 720b can include the same material as the metal pattern 520 of FIG. 5 but are not limited thereto.

The display panel according to embodiments of the present disclosure can further include a first coating layer 710a coated on the first metal structure 720a and a second coating layer 710b coated on the second metal structure 720b.

In the display panel according to embodiments of the present disclosure, the first coating layer 710a and the second coating layer 710b can include at least one of molybdenum (Mo), molybdenum-titanium (MoTi), vanadium (V), niobium (Nb), tantalum (Ta), hafnium (Hf), zirconium (Zr), titanium (Ti), cerium (Ce), lanthanum (La), yttrium (Y), scandium (Sc), and lithium (Li). For example, the first coating layer 710a and the second coating layer 710b can include the same material as the metal coating layer 510 of FIG. 5 but are not limited thereto.

In the display panel according to embodiments of the present disclosure, when the first coating layer 710a and the second coating layer 710b include the same material as the metal coating layer 510 of FIG. 5, they can capture hydrogen diffusing from the first encapsulation layer 341, which includes silicon nitride, thereby preventing hydrogen-induced conductivity of the active layer that contains an oxide semiconductor.

The display apparatus according to embodiments of the present disclosure can further include a plurality of color filters disposed between the substrate SUB and the first metal structure 720a and overlapping the pixel electrode PE.

The plurality of color filters can include a first color filter CF1 and a second color filter CF2. For example, the first color filter CF1 can correspond to the first subpixel SP1 that emits blue (B) light, and the second color filter CF2 can correspond to the second subpixel SP2 that emits green (G) light.

Further, one end of the second color filter CF2 can overlap with the first metal structure 720a, and the other end of the second color filter CF2 can overlap with the second metal structure 720b. Additionally, one end of the first color filter CF1 can overlap with a different metal structure, and the other end of the first color filter CF1 can overlap with the first metal structure 720a.

The first metal structure 720a and the first coating layer 710a can overlap the boundary between the first color filter CF1 and the second color filter CF2. In other words, the first metal structure 720a and the first coating layer 710a can be a driving signal wiring disposed between the first subpixel SP1 and the second subpixel SP2. The second metal structure 720b and the second coating layer 710b can also function as a driving signal wiring supplying power signals or image signals to the subpixels.

By including the first metal structure 720a and the first coating layer 710a arranged as described above, the display panel according to embodiments of the present disclosure can prevent color mixing between the first subpixel SP1 and the second subpixel SP2.

For example, the light emitted from the light-emitting device ED of the first subpixel SP1 toward the lower surface of the display panel (hereinafter referred to as “first light”) can travel in at least one direction in a straight line. Accordingly, the first light may not only be incident on the first color filter CF1 but also on the adjacent second color filter CF2.

Likewise, the light emitted from the light-emitting device ED of the second subpixel SP2 toward the lower surface of the display panel (hereinafter referred to as “second light”) can travel in at least one direction in a straight line. Accordingly, the second light can be incident not only on the first color filter CF1 but also on the second color filter CF2, which is adjacent to the first color filter CF1.

As a result, blue (B) light and green (G) light can overlap, leading to color mixing. The mixed light can be emitted outside the display panel, thereby degrading display quality by reducing color viewing angles.

The first coating layer 710a, which is disposed in an overlapping region with the boundary between the first color filter CF1 and the second color filter CF2, can reflect the first light, which is emitted toward the second color filter CF2, back toward the first color filter CF1. Similarly, the first coating layer 710a can reflect the second light, which is emitted toward the first color filter CF1, back toward the second color filter CF2.

As a result, the first coating layer 710a, which is coated on the first metal structure 720a, can prevent color mixing between the first subpixel SP1 and the second subpixel SP2, improve the degradation of color viewing angles, and enhance the emission efficiency of each subpixel.

Hereinafter, with reference to FIG. 6, the structure capable of preventing color mixing between the first subpixel SP1 and the second subpixel SP2 in the display panel according to embodiments of the present disclosure will be described in more detail.

In the display panel according to embodiments of the present disclosure, the distance from the upper surface of the first coating layer 710a to the organic layer EL (hereinafter referred to as “first length D1”) can be smaller than the thickness of the pixel electrode PE (hereinafter referred to as “second length D2”).

The upper surface of the first coating layer 710a is not in contact with the organic layer EL, but the first length D1 can be minimized to be smaller than the second length D2. Accordingly, the first light and the second light do not leak through the junction between the upper surface of the first coating layer 710a and the organic layer EL, do not disrupt the flow of carriers inside the light-emitting device ED, and can prevent color mixing between the first subpixel SP1 and the second subpixel SP2.

In the display panel according to embodiments of the present disclosure, a first buffer layer 631 can be disposed between the upper surface of the first coating layer 710a and the organic layer EL. Accordingly, the thickness of the first buffer layer 631 can be less than the second length D2.

The thickness of the first buffer layer 631 can be less than the thickness of the second buffer layer 632.

In addition, since the first buffer layer 631, which has a high density, is disposed in the display panel according to embodiments of the present disclosure, it can block hydrogen diffusing from the first encapsulation layer 341, which includes silicon nitride, thereby preventing hydrogen-induced conductivity of the active layer that contains an oxide semiconductor.

In the display panel according to embodiments of the present disclosure, the distance from the lower surface of the first metal structure 720a to the plurality of color filters (hereinafter referred to as “third length D3”) can be smaller than the thickness of the pixel electrode PE. In other words, the third length D3 can be smaller than the second length D2.

Since the third length D3 is minimized to be smaller than the second length D2, the first light and the second light do not leak through the gap between the lower surface of the first metal structure 720a and the plurality of color filters, thereby preventing color mixing between the first subpixel SP1 and the second subpixel SP2.

In the display panel according to embodiments of the present disclosure, the second insulating layer 650 can be disposed beneath the first insulating layer 640 and can be in contact with the lower surface of the first head part 721a and the second head part 721b. Accordingly, the thickness of the second insulating layer 650 can be less than the second length D2.

The thickness of the second insulating layer 650 can be smaller than the thickness of the first insulating layer 640.

FIG. 7 to FIG. 15 are process cross-sectional views illustrating steps for forming the structures shown in FIG. 5 and FIG. 6 according to embodiments of the present disclosure.

Referring to FIG. 7, a sub-adhesion layer PMMA can be laminated on a sub-substrate SUB′. The sub-substrate SUB′ can be a glass substrate. The sub-adhesion layer PMMA can include polymethyl methacrylate (PMMA). A patterning process can be performed on the sub-adhesion layer PMMA to form the pixel electrode PE. (Steps S10a, S10b)

A metal coating layer 510 and a metal pattern 520 can be formed on the pixel electrode PE. By selectively variously exposing light transmittance using a half-tone mask, patterning can be performed so that only the pixel electrode PE remains in the first and second emission regions. (Step S10a)

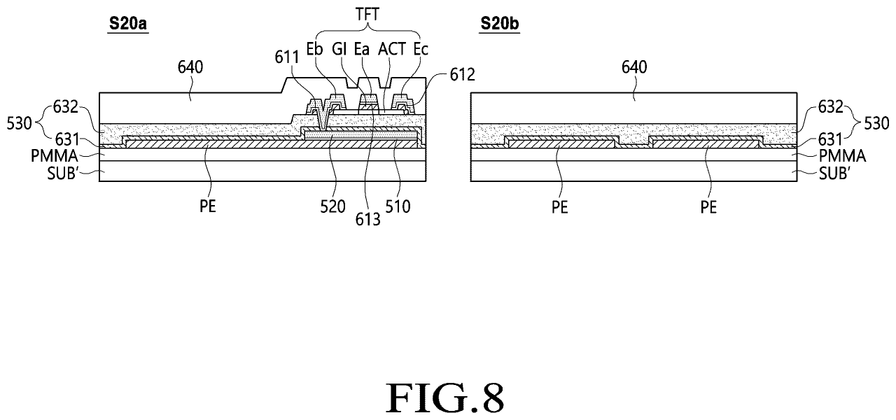

Referring to FIG. 8, a first buffer layer 631 can be laminated to cover the pixel electrode PE, the metal coating layer 510, and the metal pattern 520. The first buffer layer 631 can be laminated with a thickness thinner than that of the pixel electrode PE and thinner than that of the second buffer layer 632. After laminating the first buffer layer 631, a dehydrogenation process through heat treatment can be performed. (Steps S20a, S20b)

A second buffer layer 632 can be laminated to cover the first buffer layer 631. The first buffer layer 631 and the second buffer layer 632 can be inorganic insulating layers, wherein the first buffer layer 631 can include silicon nitride, and the second buffer layer 632 can include silicon oxide. (Steps S20a, S20b)

A thin-film transistor TFT can be formed on the second buffer layer 632. First, an active layer ACT can be patterned on the upper surface of the second buffer layer 632. Impurity ions can be doped into both sides of the active layer ACT so that they function as a source region and/or a drain region, while the middle portion of the active layer ACT serves as a channel region. The active layer ACT can be formed of an oxide that includes at least one of gallium (Ga), indium (In), zinc (Zn), and oxygen (O). (Step S20a)

A gate insulating layer GI can be patterned on the active layer ACT. The gate insulating layer GI can be an inorganic insulating layer that includes silicon oxide but is not limited thereto. While depositing the gate insulating layer GI, contact holes disposed in the second buffer layer 632 and the first buffer layer 631 can be formed simultaneously. (Step S20a)

First to third electrode coating layers 611, 612, and 613 can be patterned on the gate insulating layer GI. A source electrode Eb can be formed on the first electrode coating layer 611, a drain electrode Ec can be formed on the second electrode coating layer 612, and a gate electrode Ea can be formed on the third electrode coating layer 613. The first electrode coating layer 611 and the source electrode Eb can be electrically connected to the metal pattern 520 through the contact holes disposed in the second buffer layer 632 and the first buffer layer 631. (Step S20a)

A first insulating layer 640 can be laminated to cover the second buffer layer 632 and the thin-film transistor TFT. The first insulating layer 640 can be an inorganic insulating layer that includes silicon oxide but is not limited thereto. (Steps S20a, S20b)

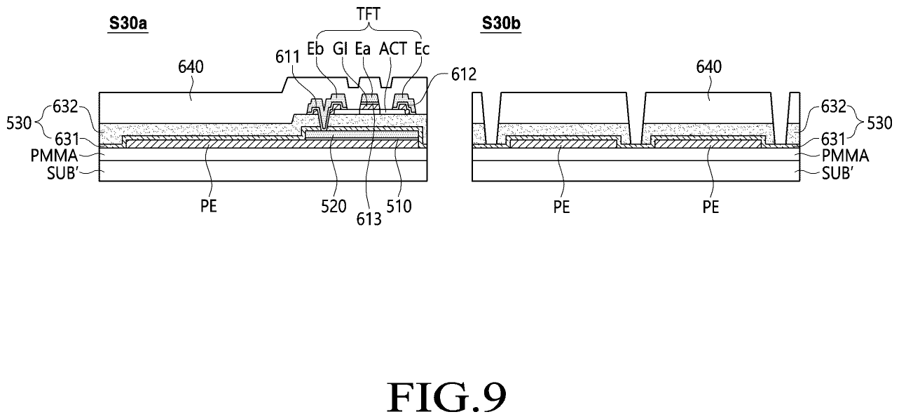

Referring to FIG. 9, a plurality of holes penetrating the first insulating layer 640 and a plurality of grooves on the upper surface of the buffer layer can be formed through an etching process. When a high-concentration BOE (Buffered Oxide Etchant) solution is used in the process of etching the buffer layer 530, the etching rates (Å/sec) of the first buffer layer 631 and the second buffer layer 632 can differ. The etching rate of the second buffer layer 632, which includes silicon oxide, can be higher than that of the first buffer layer 631, which includes silicon nitride. Accordingly, by adjusting the etching time of the buffer layer 530, the second buffer layer 632 can be completely removed, while the first buffer layer 631 remains. (Steps S30a, S30b)

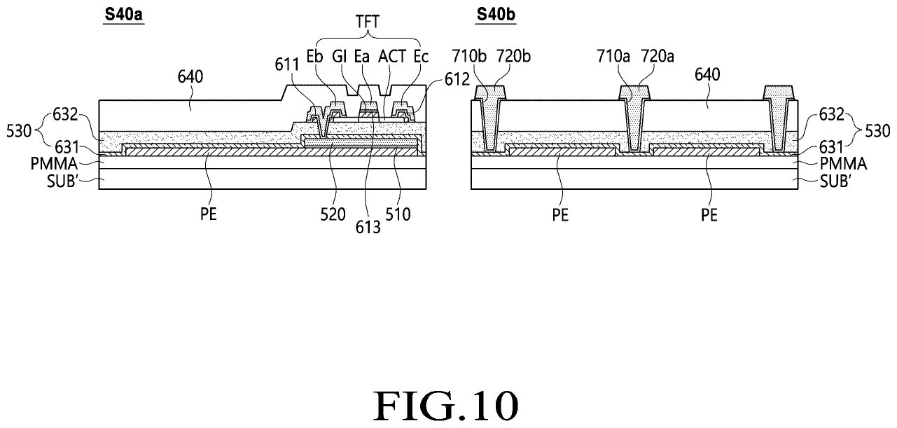

Referring to FIG. 10, the first coating layer 710a and the second coating layer 710b can be deposited to cover the etched portions of the first insulating layer 640 and the buffer layer 530. The first metal structure 720a can be formed on the first coating layer 710a, and the second metal structure 720b can be formed on the second coating layer 710b. (Steps S40a, S40b)

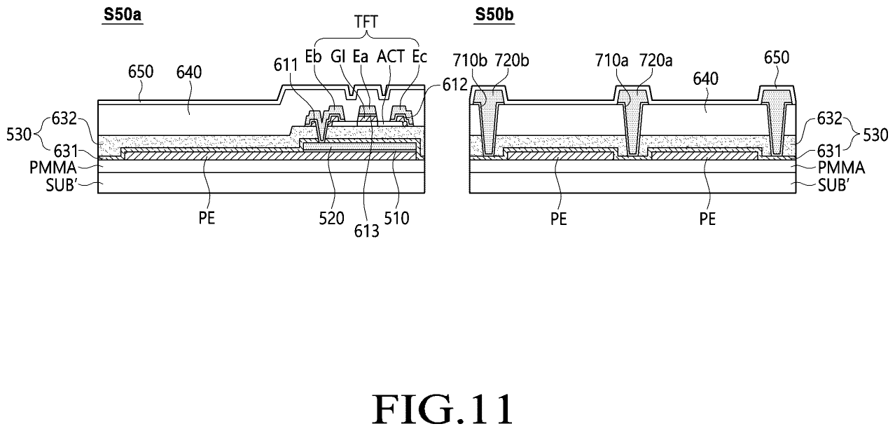

Referring to FIG. 11, a second insulating layer 650 can be laminated to cover the upper surfaces of the first insulating layer 640, the first metal structure 720a, and the second metal structure 720b. The second insulating layer 650 can be laminated with a thickness thinner than that of the pixel electrode PE and thinner than that of the first insulating layer 640. The second insulating layer 650 can have excellent step coverage characteristics and can be deposited using a CVD (Chemical Vapor Deposition) or ALD (Atomic Layer Deposition) technique, which enables the formation of a thinner film. However, the present disclosure is not limited thereto. (Steps S50a, S50b)

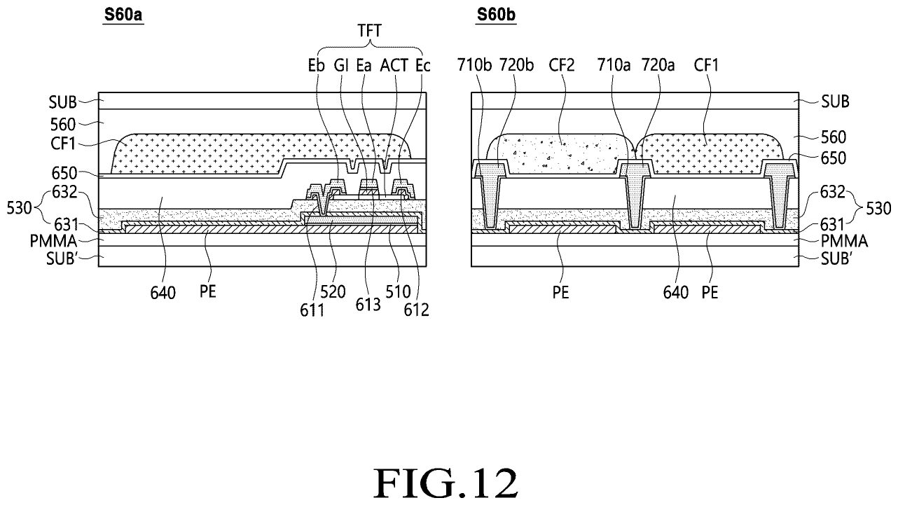

Referring to FIG. 12, a first color filter CF1 and a second color filter CF2 can be formed on the second insulating layer 650 so that each overlaps with the pixel electrode PE. The first metal structure 720a and the first coating layer 710a are arranged to overlap the boundary between the first color filter CF1 and the second color filter CF2, thereby preventing color mixing between the first subpixel SP1 and the second subpixel SP2. Accordingly, banks, which are typically formed on the pixel electrode PE to separate the emission regions of the subpixels may not be arranged. The display panel according to embodiments of the present disclosure does not include banks, thereby increasing the emission aperture ratio. Additionally, since the patterning process for bank formation is not required, process optimization can be achieved. (Step S60b)

An adhesion layer 560 can be laminated to cover the first color filter CF1 and the second color filter CF2, and a substrate SUB can be disposed on the adhesion layer 560. The substrate SUB can be a glass substrate, and the adhesion layer 560 can include a transparent resin to bond the substrate SUB to the color filters CF1 and CF2 and the second insulating layer 650. (Steps S60a, S60b)

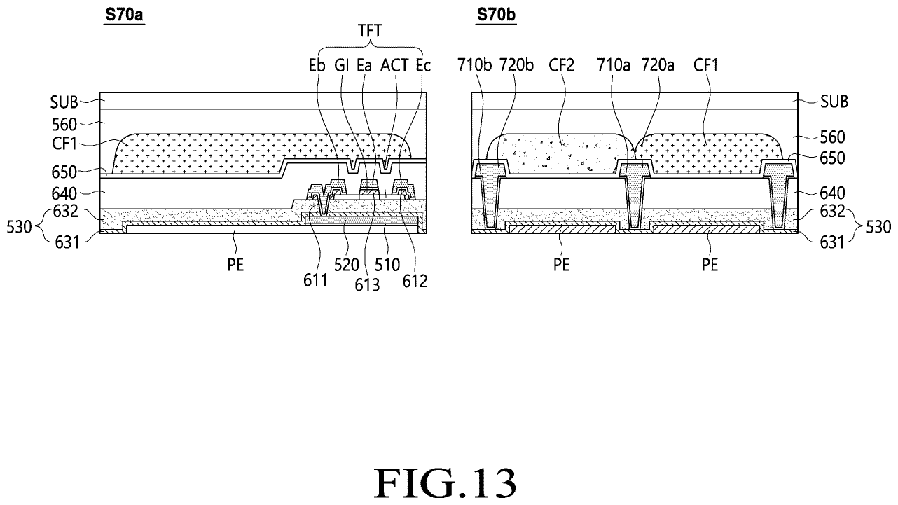

Referring to FIG. 13, the sub-substrate SUB′ and the sub-adhesion layer PMMA can be removed from the laminated structure formed as described above. When laser light is irradiated onto the lower surface of the sub-substrate SUB′, the sub-adhesion layer PMMA can be detached from the lower surface of the pixel electrode PE and the first buffer layer 631. (Steps S70a, S70b)

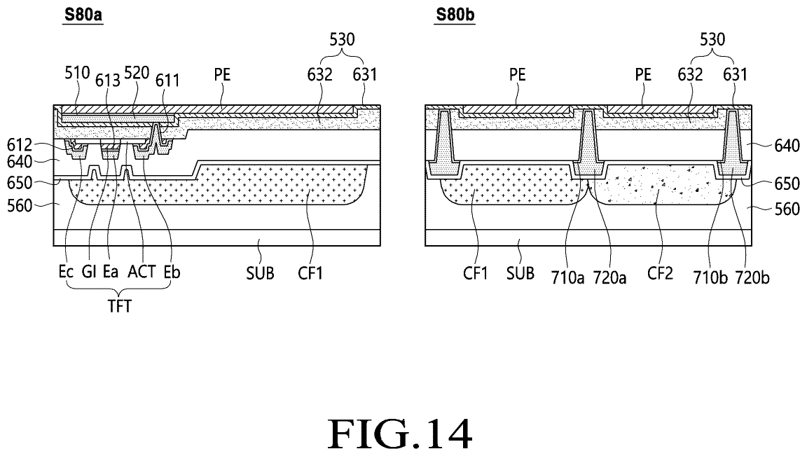

Referring to FIG. 14, the laminated structure formed as described above can be flipped so that the pixel electrode PE is positioned at the top. (Steps S80a, S80b)

The pixel electrode PE, which already has a planarized upper surface and a planarized lower surface, is positioned at the top. Thus, the light-emitting device ED can still be formed in a planarized manner without the need for a planarization layer to eliminate the height differences caused by the thin-film transistor TFT, the first color filter CF1, and the second color filter CF2. Since planarization layers are typically formed using organic materials, their moisture barrier reliability can decrease. The display panel according to embodiments of the present disclosure does not include a planarization layer, thereby improving moisture barrier reliability and achieving process optimization by eliminating the additional patterning process required for planarization layer formation. (Step S80a)

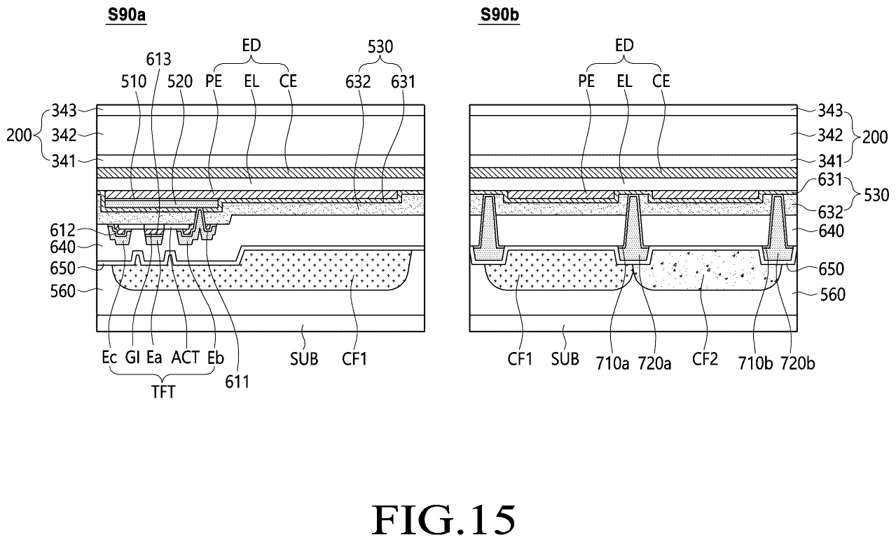

Referring to FIG. 15, an organic layer EL can be deposited on the pixel electrode PE and the first buffer layer 631. A common electrode CE can be deposited on the organic layer EL. Additionally, an encapsulation layer 200 can be formed to cover the common electrode CE, wherein the encapsulation layer 200 can be sequentially laminated as first to third encapsulation layers 341, 342, and 343. (Steps S90a, S90b)

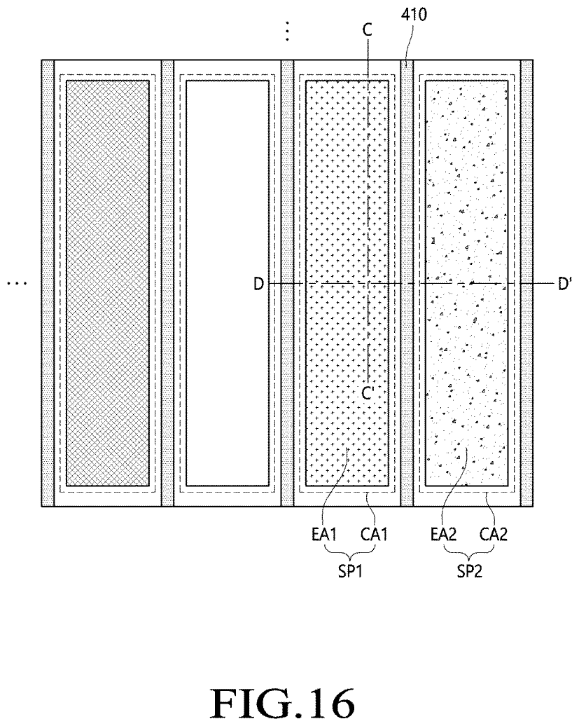

FIG. 16 is a plan view illustrating a portion of the plurality of subpixels in the display panel according to embodiments of the present disclosure.

Referring to FIG. 16, the plurality of subpixels can include a first subpixel SP1, a second subpixel SP2, and a driving signal wiring 410. The first subpixel SP1 can include a first emission region EA1 and a first circuit region CA1, while the second subpixel SP2 can include a second emission region EA2 and a second circuit region CA2. Descriptions overlapping with the configuration of FIG. 3 can be omitted.

The first circuit region CA1 and the second circuit region CA2 can overlap with the first emission region EA1 and the second emission region EA2, respectively. In other words, the first emission region EA1 is positioned on the first circuit region CA1, and the second emission region EA2 is positioned on the second circuit region CA2, thereby forming a top-emission structure for the first subpixel SP1 and the second subpixel SP2.

In FIG. 16, line C-C′ represents a cutting line that traverses the first emission region EA1 and the first circuit region CA1 of the first subpixel SP1. Further, line D-D′ represents a cutting line extending from the first subpixel SP1 across the driving signal wiring 410 to the second subpixel SP2.

Hereinafter, the cross-sectional structures of the display panel along lines C-C′ and D-D′ in accordance with embodiments of the present disclosure will be described in detail.

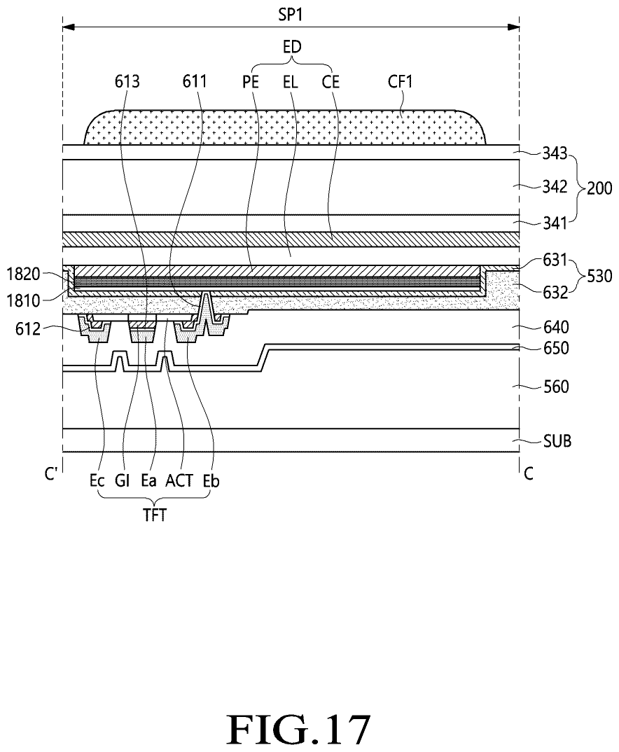

FIG. 17 is a cross-sectional view of the display panel according to embodiments of the present disclosure, taken along line C-C′ in FIG. 16.

Referring to FIG. 17, the display panel according to embodiments of the present disclosure can include a substrate SUB, an adhesion layer 560, a first insulating layer 640, a second insulating layer 650, a thin-film transistor TFT, first, second and third electrode coating layers 611, 612, and 613, a first buffer layer 631, a second buffer layer 632, a metal coating layer 1810, a metal pattern 1820, a pixel electrode PE, an organic layer EL, a common electrode CE, an encapsulation layer 200, and a first color filter CF1. Descriptions overlapping with the configuration of FIG. 5 can be omitted.

In the display panel according to embodiments of the present disclosure, the common electrode CE can be disposed on the organic layer EL.

When the display apparatus according to embodiments of the present disclosure has a top-emission structure, the common electrode CE can transmit the light emitted from the light-emitting device ED toward the front side of the display panel. For example, the common electrode CE can be formed of a transparent conductive layer or a thin metal material with high light transmittance, but is not limited thereto.

For example, the common electrode CE can be made of a low-work-function metallic material such as a metal alloy containing magnesium-silver (MgAg) or a metal alloy containing ytterbium (Yb).

In the display panel according to embodiments of the present disclosure, the encapsulation layer 200 can be disposed on the common electrode CE.

When the display apparatus according to embodiments of the present disclosure has a top-emission structure, the encapsulation layer 200 can transmit the light emitted from the light-emitting device ED toward the front side of the display panel. For example, the encapsulation layer 200 can be composed of two or more layers in which organic and inorganic films with high light transmittance are alternately laminated.

For example, the first encapsulation layer 341 can include silicon nitride, and the third encapsulation layer 343 can include at least one of silicon nitride, silicon oxide (SiOx), or silicon oxynitride (SiOxNy). In this case, the second encapsulation layer 342 can function as a foreign material compensation layer and can include silicon oxycarbon (SiOCz), an acryl-based material (Acryl), or an epoxy-based resin (Epoxy).

In the display panel according to embodiments of the present disclosure, the first color filter CF1 can be disposed on the encapsulation layer 200 and can overlap with the pixel electrode PE.

In the display panel according to embodiments of the present disclosure, the metal pattern 1820 can entirely overlap with the pixel electrode PE.

In the display panel according to embodiments of the present disclosure, the metal pattern 1820 can overlap with the emission region. The emission region of the first subpixel SP1, i.e., the first emission region, can be an area where the pixel electrode PE and the organic layer EL overlap.

When the display apparatus according to embodiments of the present disclosure has a top-emission structure, the metal pattern 1820 can reflect the light emitted from the light-emitting device ED toward the front of the display panel. For example, the metal pattern 1820 can include a metal material with high reflectivity, but is not limited thereto.

For example, the metal pattern 1820 can include at least one of aluminum (Al) or a silver (Ag) alloy, wherein the silver (Ag) alloy can be an alloy of silver (Ag), palladium (Pd), and copper (Cu).

In other words, since the metal pattern 1820 entirely overlaps with the pixel electrode PE, it can also overlap with the first emission region. As a result, the light emitted from the light-emitting device ED toward the lower surface can be reflected by the metal pattern 1820, which includes a highly reflective metal, and then emitted outside the display panel. Accordingly, the larger the area where the metal pattern 1820 overlaps with the first emission region, the higher the emission efficiency of the first subpixel SP1.

In the display panel according to embodiments of the present disclosure, the metal coating layer 1810 can be disposed beneath the metal pattern 1820, have planarized upper and lower surfaces, and entirely overlap with the pixel electrode PE.

In the display panel according to embodiments of the present disclosure, the source electrode Eb can be electrically connected to the lower surface of the metal coating layer 1810 through the first electrode coating layer 611. The source electrode Eb and the first electrode coating layer 611 can be electrically connected to the lower surface of the metal coating layer 1810 exposed through a contact hole penetrating the buffer layer.

As a result, by arranging the metal coating layer 1810 and the first buffer layer 631, which trap or block hydrogen diffusing from the first encapsulation layer 341 including silicon nitride, hydrogen-induced conductivity of the active layer ACT including an oxide semiconductor can be prevented.

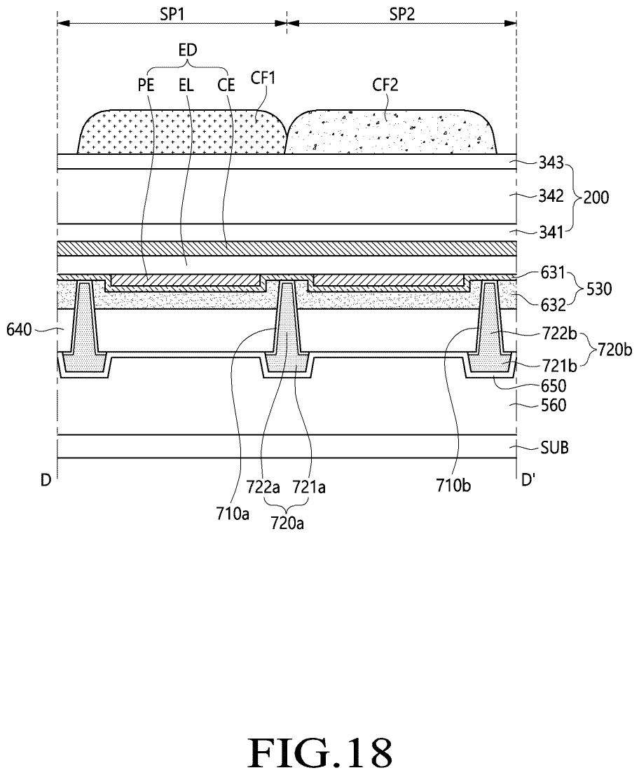

FIG. 18 is a cross-sectional view of the display panel according to embodiments of the present disclosure, taken along line D-D′ in FIG. 16.

Referring to FIG. 18, the display panel according to embodiments of the present disclosure can include a substrate SUB, an adhesion layer 560, a first insulating layer 640, a second insulating layer 650, a first buffer layer 631, a second buffer layer 632, a pixel electrode PE, an organic layer EL, a common electrode CE, an encapsulation layer 200, first and second color filters (CF1, CF2), first and second metal structures 720a and 720b, and first and second coating layers 710a and 710b. Descriptions overlapping with the configurations of FIG. 6 and FIG. 17 can be omitted.

When the display apparatus according to embodiments of the present disclosure has a top-emission structure, the plurality of color filters, i.e., the first color filter CF1 and the second color filter CF2, can be disposed on the encapsulation layer 200 and can overlap with the pixel electrode PE.

In the display panel according to embodiments of the present disclosure, by arranging the first and second coating layers 710a and 710b, and the first buffer layer 631, which capture or block hydrogen diffusing from the first encapsulation layer 341 containing silicon nitride, hydrogen-induced conductivity of the active layer including an oxide semiconductor can be prevented.

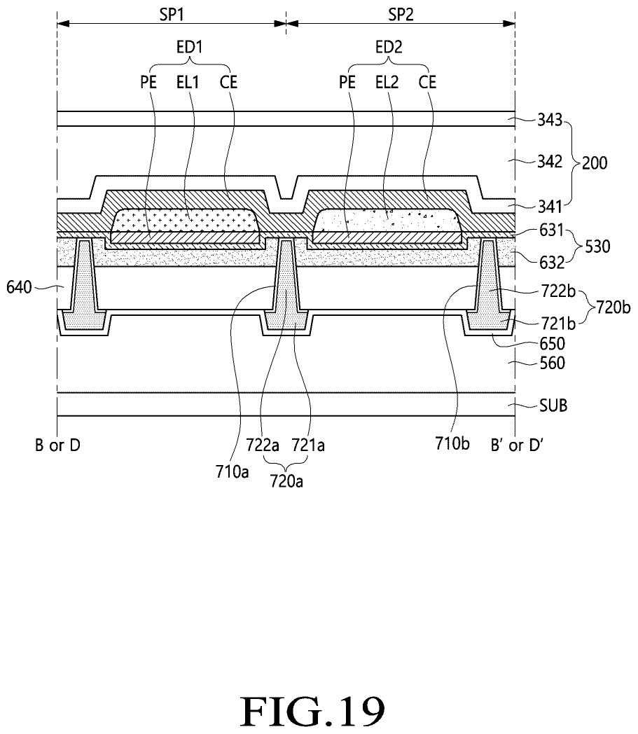

FIG. 19 is a cross-sectional view of the display panel according to embodiments of the present disclosure, taken along line B-B′ in FIG. 3 or line D-D′ in FIG. 16.

Particularly, FIG. 19 is a cross-sectional view including a plurality of organic light-emitting layers that emit light of different wavelengths, i.e., red (R), green (G), and blue (B), in the display panel according to embodiments of the present disclosure. FIG. 19 is a cross-sectional view applicable to both a top-emission structure and a bottom-emission structure in the display apparatus according to embodiments of the present disclosure.

Referring to FIG. 19, the display panel according to embodiments of the present disclosure can include a substrate SUB, an adhesion layer 560, a first insulating layer 640, a second insulating layer 650, a first buffer layer 631, a second buffer layer 632, a pixel electrode PE, a common electrode CE, an encapsulation layer 200, first and second metal structures 720a and 720b, and first and second coating layers 710a and 710b. Descriptions overlapping with the configuration of FIG. 18 can be omitted.

The display panel according to embodiments of the present disclosure can further include a plurality of organic light-emitting layers disposed on the pixel electrode PE.

In the display panel according to embodiments of the present disclosure, the plurality of organic light-emitting layers can include a first organic light-emitting layer EL1 and a second organic light-emitting layer EL2 disposed apart from the first organic light-emitting layer EL1.

For example, the first organic light-emitting layer EL1 can emit blue (B) light, and the second organic light-emitting layer EL2 can emit green (G) light.

The first metal structure 720a can overlap with the region where the first organic light-emitting layer EL1 and the second organic light-emitting layer EL2 are spaced apart from each other.

The common electrode CE can be disposed to cover the plurality of organic light-emitting layers, and the distance from the upper surface of the first coating layer 710a to the common electrode CE can be smaller than the thickness of the pixel electrode PE.

As a result, when the display apparatus according to embodiments of the present disclosure has a bottom-emission structure, it can prevent the first light and the second light from leaking through the gap between the upper surface of the first coating layer 710a and the common electrode CE, while preventing color mixing between the first subpixel SP1 and the second subpixel SP2.

When the display apparatus according to embodiments of the present disclosure has either a bottom-emission or top-emission structure, the first and second coating layers 710a and 710b and the first buffer layer 631, which trap or block hydrogen diffusing from the first encapsulation layer 341 including silicon nitride, can be arranged, thereby preventing hydrogen-induced conductivity of the active layer including an oxide semiconductor.

When the display apparatus according to embodiments of the present disclosure has a bottom-emission structure, the common electrode CE can include a metal material with high reflectivity but is not limited thereto.

When the display apparatus according to embodiments of the present disclosure has a top-emission structure, the common electrode CE can be formed of a transparent conductive layer or a thin metal material with high light transmittance, but is not limited thereto.

When the display apparatus according to embodiments of the present disclosure has a bottom-emission structure, the encapsulation layer 200 can include an FSPM encapsulation structure or a TFE encapsulation structure.

When the display apparatus according to embodiments of the present disclosure has a top-emission structure, the encapsulation layer 200 can include a TFE encapsulation structure.

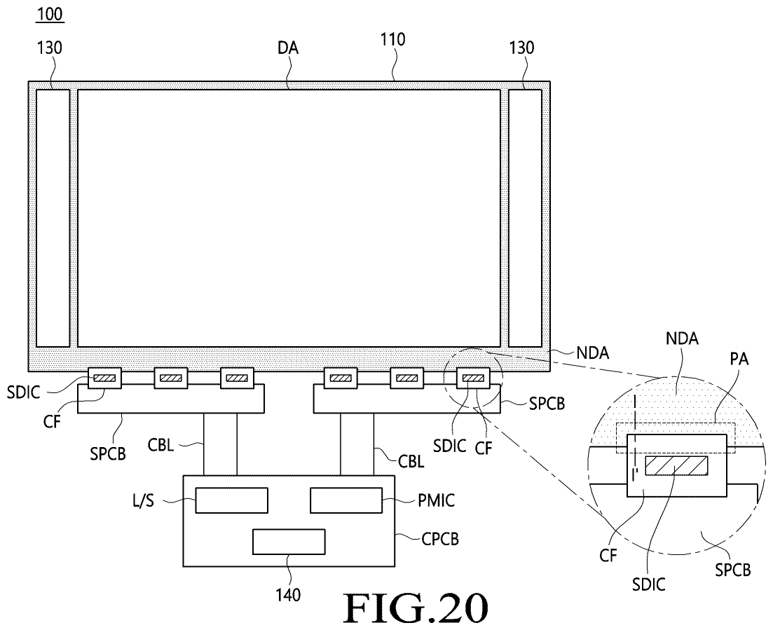

FIG. 20 illustrates a display apparatus according to embodiments of the present disclosure.

Particularly, FIG. 20 can be an example system implementation diagram of the display apparatus according to embodiments of the present disclosure, and descriptions overlapping with the configuration of FIG. 1 can be omitted.

Referring to FIG. 20, the substrate can include a display area DA, where images can be displayed, and a non-display area NDA, which is located outside the display area DA and includes a plurality of pads. Hereinafter, a detailed description will be provided for a pad area PA, where the plurality of pads are arranged.

The data driving circuit can include a plurality of source driver integrated circuits SDIC and can be implemented using a Chip On Film (COF) method. Each of the plurality of source driver integrated circuits SDIC can be mounted on a circuit film CF connected to the non-display area NDA of the display panel 110. The circuit film CF is also referred to as a flexible printed circuit FPC.

The display apparatus according to embodiments of the present disclosure can include at least one source printed circuit board SPCB for circuit connections between the plurality of source driver integrated circuits SDIC and other components, such as a controller 140, a level shifter L/S, and a power management integrated circuit PMIC. Additionally, a control printed circuit board CPCB can be included to mount control components and various electrical devices.

At least one source printed circuit board SPCB can be connected to a circuit film CF on which the source driver integrated circuit SDIC is mounted. For example, the circuit film CF with the source driver integrated circuit SDIC mounted can have one side electrically connected to the display panel 110 and the other side electrically connected to the source printed circuit board SPCB.

In this case, by arranging a plurality of pads in the region where one side of the circuit film CF overlaps with the non-display area NDA, the circuit film CF and the display panel 110 can be electrically connected. The plurality of pads can include pads connected to driving signal wirings for driving subpixels. At least one of the plurality of pads can be a lighting test pad used in the inspection process during the manufacturing of the display panel.

In FIG. 20, line I-I′ represents a cutting line traversing from the non-display area NDA of the pad area PA to the circuit film CF. Hereinafter, a detailed description will be provided for the cross-sectional structure of the display apparatus taken along line I-I′ according to embodiments of the present disclosure.

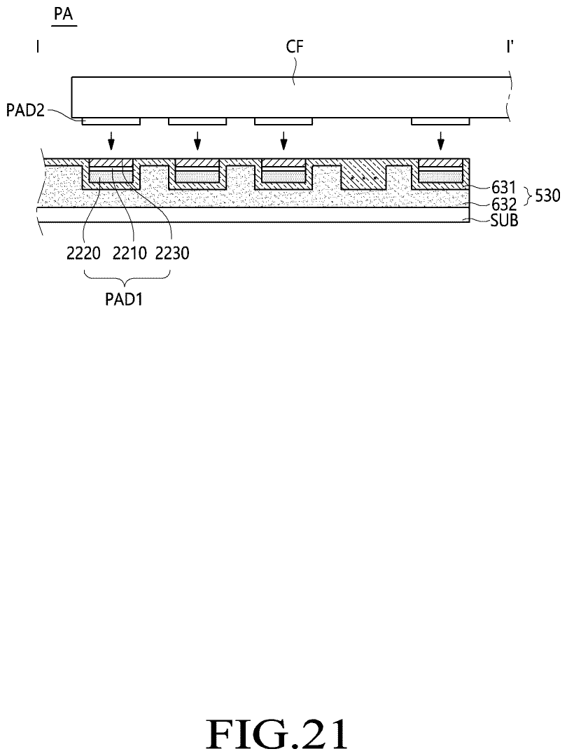

FIG. 21 is a cross-sectional view of the display apparatus according to embodiments of the present disclosure, taken along line I-I′ in FIG. 20.

Referring to FIG. 21, the display apparatus according to embodiments of the present disclosure can include a substrate SUB extending from the display area DA, a second buffer layer 632 disposed on the substrate SUB, a first buffer layer 631 disposed on the second buffer layer 632, and a plurality of pads PAD1.

Each of the plurality of pads PAD1 can include a first conductive layer 2220 disposed on the substrate SUB, a second conductive layer 2210 disposed on the first conductive layer 2220, and a third conductive layer 2230 disposed on the second conductive layer 2210. The upper surface of the third conductive layer 2230 can be planarized with the upper surface of the first buffer layer 631.

In the display apparatus according to embodiments of the present disclosure, the first conductive layer 2220 can include the same material as the metal pattern 520 in FIG. 4, the second conductive layer 2210 can include the same material as the metal coating layer 510 in FIG. 4, and the third conductive layer 2230 can include the same material as the pixel electrode PE in FIG. 4.

A plurality of upper pads PAD2 can be disposed on the lower portion of the circuit film CF. By bringing the lower surface of each of multiple upper pads PAD2 into contact with the upper surface of the third conductive layer 2230, the circuit film CF and the display panel 110 can be electrically connected.

The display apparatus according to embodiments of the present disclosure can be described as follows.

The display apparatus according to embodiments of the present disclosure can include a substrate including a plurality of subpixels, a thin-film transistor disposed on the substrate, a buffer layer disposed on the thin-film transistor, a pixel electrode disposed on the buffer layer and having planarized upper and lower surfaces, an organic layer disposed on the pixel electrode, a common electrode disposed on the organic layer, an encapsulation layer disposed on the common electrode, and a metal pattern disposed between the buffer layer and the pixel electrode, overlapping at least a portion of the pixel electrode and having planarized upper and lower surfaces.

The display apparatus according to embodiments of the present disclosure can further include a metal coating layer disposed on the metal pattern and having planarized upper and lower surfaces.

According to the display apparatus of the present disclosure, the metal coating layer can include at least one of molybdenum (Mo), molybdenum titanium (MoTi), vanadium (V), niobium (Nb), tantalum (Ta), hafnium (Hf), zirconium (Zr), titanium (Ti), cerium (Ce), lanthanum (La), yttrium (Y), scandium (Sc), or lithium (Li).

According to the display apparatus of the present disclosure, the substrate can include a display area DA where images can be displayed, and a non-display area NDA which is an area where images are not displayed, located outside the display area DA and including a plurality of pads. Each of the plurality of pads can include a first conductive layer disposed on the substrate, a second conductive layer disposed on the first conductive layer, and a third conductive layer disposed on the second conductive layer. The first conductive layer can include the same material as the metal pattern, the second conductive layer can include the same material as the metal coating layer, and the third conductive layer can include the same material as the pixel electrode.

According to the display apparatus of the present disclosure, the buffer layer can include a first buffer layer and a second buffer layer disposed beneath the first buffer layer, and the first buffer layer and the second buffer layer can include different inorganic materials.

According to the display apparatus of the present disclosure, the thickness of the first buffer layer can be smaller than the thickness of the second buffer layer.

According to the display apparatus of the present disclosure, the thickness of the first buffer layer can be smaller than the thickness of the pixel electrode.

The display apparatus according to embodiments of the present disclosure can further include a first insulating layer disposed between the substrate and the thin-film transistor and a second insulating layer disposed beneath the first insulating layer, wherein the thickness of the second insulating layer can be smaller than the thickness of the first insulating layer.

According to the display apparatus of the present disclosure, the thickness of the second insulating layer can be smaller than the thickness of the pixel electrode.

According to the display apparatus of the present disclosure, the encapsulation layer can include a first encapsulation layer, a second encapsulation layer disposed on the first encapsulation layer, and a third encapsulation layer disposed on the second encapsulation layer, wherein at least one of the first encapsulation layer and the third encapsulation layer can include silicon nitride.

According to the display apparatus of the present disclosure, the thin-film transistor can include a gate electrode, an active layer disposed on the gate electrode, a gate insulating film disposed between the gate electrode and the active layer, a source electrode connected to the lower surface of a portion of the active layer, and a drain electrode connected to the lower surface of another portion of the active layer, wherein the active layer can include an oxide semiconductor and can overlap with the metal coating layer.

In the display apparatus according to embodiments of the present disclosure, the encapsulation layer further includes a first encapsulation layer that is in contact with the upper surface of the common electrode. The hydrogen concentration of the first encapsulation layer can be higher than that of the active layer.

The display apparatus according to embodiments of the present disclosure can further include a first electrode coating layer disposed on the source electrode, a second electrode coating layer disposed on the drain electrode, and a third electrode coating layer disposed on the gate electrode, wherein the first to third electrode coating layers can include at least one of molybdenum (Mo), molybdenum titanium (MoTi), vanadium (V), niobium (Nb), tantalum (Ta), hafnium (Hf), zirconium (Zr), titanium (Ti), cerium (Ce), lanthanum (La), yttrium (Y), scandium (Sc), or lithium (Li).

According to the display apparatus of the present disclosure, the source electrode can be electrically connected to the lower surface of the metal pattern through the first electrode coating layer, and the source electrode and the first electrode coating layer can be electrically connected to the lower surface of the metal pattern exposed through a contact hole penetrating the buffer layer.

The display apparatus according to embodiments of the present disclosure can further include a first color filter disposed between the substrate and the thin-film transistor TFT, overlapping with the pixel electrode and corresponding to a first subpixel among multiple subpixels, and the metal coating layer may not overlap with a portion of the pixel electrode that overlaps with the emission region of the first subpixel.

The display apparatus according to embodiments of the present disclosure can further include a first color filter disposed on the pixel electrode and overlapping with the pixel electrode, and a metal coating layer disposed beneath the metal pattern and having planarized upper and lower surfaces, wherein the metal pattern can entirely overlap with the pixel electrode.

The display apparatus according to embodiments of the present disclosure can include a substrate including a subpixel and a driving signal wiring, a first insulating layer disposed on the substrate, a buffer layer disposed on the first insulating layer, a pixel electrode disposed on the buffer layer and having planarized upper and lower surfaces, a first metal structure positioned on one side of the pixel electrode, and a second metal structure positioned on the other side of the pixel electrode.

The display apparatus according to embodiments of the present disclosure can further include a first coating layer coated on a first metal structure and a second coating layer coated on a second metal structure. The first and second coating layers can include at least one of molybdenum (Mo), molybdenum titanium (MoTi), vanadium (V), niobium (Nb), tantalum (Ta), hafnium (Hf), zirconium (Zr), titanium (Ti), cerium (Ce), lanthanum (La), yttrium (Y), scandium (Sc), or lithium (Li).

The display apparatus according to embodiments of the present disclosure can further include an organic layer disposed on the pixel electrode. The distance from the upper surface of the first coating layer to the organic layer can be smaller than the thickness of the pixel electrode.

The display apparatus according to embodiments of the present disclosure can further include a plurality of color filters disposed between the substrate and the first metal structure. The distance from the lower surface of the first metal structure to the plurality of color filters can be smaller than the thickness of the pixel electrode.

According to the display apparatus of embodiments of the present disclosure, a plurality of color filters can include a first color filter and a second color filter overlapping the pixel electrode. One end of the second color filter can overlap the first metal structure, and the other end can overlap the second metal structure.

The display apparatus according to embodiments of the present disclosure can further include a plurality of organic light-emitting layers disposed on the pixel electrode and a common electrode arranged to cover the plurality of organic light-emitting layers. The distance from the upper surface of the first coating layer to the common electrode can be smaller than the thickness of the pixel electrode.

According to embodiments of the present disclosure, the plurality of organic light-emitting layers can include a first organic light-emitting layer and a second organic light-emitting layer disposed apart from the first organic light-emitting layer. The first metal structure can overlap the region where the first and second organic light-emitting layers are spaced apart.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. For example, the disclosed embodiments are intended to illustrate the scope of the technical idea of the present disclosure.

What is claimed is:

1. A display apparatus comprising:
a substrate including a plurality of subpixels;
a thin-film transistor disposed on the substrate;
a first buffer layer disposed on the thin-film transistor;
a pixel electrode disposed on the first buffer layer;
an organic layer disposed on the pixel electrode;
a common electrode disposed on the organic layer;
an encapsulation layer disposed on the common electrode; and
a metal pattern disposed between the first buffer layer and the pixel electrode,
wherein the metal pattern overlaps at least a portion of the pixel electrode.

2. The display apparatus of claim 1, wherein the thin-film transistor comprises:
a gate electrode;
an active layer disposed on the gate electrode;
a gate insulating layer disposed between the gate electrode and the active layer;
a source electrode connected to a lower surface of a portion of the active layer; and
a drain electrode connected to a lower surface of another portion of the active layer.

3. The display apparatus of claim 2, wherein the source electrode is electrically connected to a lower surface of the metal pattern exposed through a contact hole penetrating the first buffer layer.

4. The display apparatus of claim 2, wherein the active layer comprises an oxide semiconductor and overlaps the metal pattern.

5. The display apparatus of claim 2, wherein the encapsulation layer comprises silicon nitride, and
wherein a hydrogen concentration of the encapsulation layer is higher than a hydrogen concentration of the active layer.

6. The display apparatus of claim 1, wherein the metal pattern has planarized upper and lower surfaces, and
wherein the display apparatus further comprises a metal coating layer disposed on the metal pattern, the metal coating layer having planarized upper and lower surfaces.

7. The display apparatus of claim 6, wherein the metal coating layer comprises at least one of molybdenum (Mo), molybdenum titanium (MoTi), vanadium (V), niobium (Nb), tantalum (Ta), hafnium (Hf), zirconium (Zr), titanium (Ti), cerium (Ce), lanthanum (La), yttrium (Y), scandium (Sc), or lithium (Li).

8. The display apparatus of claim 6, wherein the substrate comprises:
a display area capable of displaying an image; and
a non-display area which is an area where images are not displayed, the non-display area being located outside the display area and including a plurality of pads,
wherein each of the plurality of pads comprises:
a first conductive layer disposed on the substrate;
a second conductive layer disposed on the first conductive layer; and
a third conductive layer disposed on the second conductive layer,
wherein the first conductive layer comprises a same material as the metal pattern,
wherein the second conductive layer comprises a same material as the metal coating layer, and
wherein the third conductive layer comprises a same material as the pixel electrode.

9. The display apparatus of claim 1, further comprising a second buffer layer disposed beneath the first buffer layer,
wherein the first and second buffer layers comprise different inorganic materials, and
wherein a thickness of the first buffer layer is smaller than a thickness of the second buffer layer.

10. The display apparatus of claim 1, wherein a thickness of the first buffer layer is smaller than a thickness of the pixel electrode, and
wherein the pixel electrode has planarized upper and lower surfaces.

11. The display apparatus of claim 1, further comprising:
a first insulating layer disposed between the substrate and the thin-film transistor; and
a second insulating layer disposed beneath the first insulating layer,
wherein a thickness of the second insulating layer is smaller than a thickness of the first insulating layer or the pixel electrode.

12. The display apparatus of claim 2, further comprising:
a first electrode coating layer disposed on the source electrode;
a second electrode coating layer disposed on the drain electrode; and
a third electrode coating layer disposed on the gate electrode,
wherein each of at least one of the first to third electrode coating layers comprises at least one of molybdenum (Mo), molybdenum titanium (MoTi), vanadium (V), niobium (Nb), tantalum (Ta), hafnium (Hf), zirconium (Zr), titanium (Ti), cerium (Ce), lanthanum (La), yttrium (Y), scandium (Sc), or lithium (Li).

13. The display apparatus of claim 6, further comprising a first color filter disposed between the substrate and the thin-film transistor, the first color filter overlapping the pixel electrode and corresponding to a first subpixel among the plurality of subpixels,
wherein the metal coating layer does not overlap a portion of the pixel electrode that overlaps an emission region of the first subpixel.

14. The display apparatus of claim 1, further comprising:
a first color filter disposed on and overlapping the pixel electrode; and
a metal coating layer disposed beneath the metal pattern and having planarized upper and lower surfaces,
wherein the metal pattern entirely overlaps the pixel electrode.

15. A display apparatus comprising:
a substrate including a subpixel and a driving signal wiring;
a first insulating layer disposed on the substrate;
a buffer layer disposed on the first insulating layer;
a pixel electrode disposed on the buffer layer;
a first metal structure located on one side of the pixel electrode; and
a second metal structure located on another side of the pixel electrode,
wherein the first metal structure comprises:
a first head part disposed beneath the first insulating layer; and
a first barrier part integrally connected to the first head part and inserted into a hole of the first insulating layer and a groove formed on a lower surface of the buffer layer, and
wherein the second metal structure comprises:
a second head part disposed beneath the first insulating layer; and
a second barrier part integrally connected to the second head part and inserted into a hole of the first insulating layer and a groove formed on a lower surface of the buffer layer.

16. The display apparatus of claim 15, further comprising:
a first coating layer coated on the first metal structure; and
a second coating layer coated on the second metal structure,
wherein each of at least one of the first and second coating layers comprises at least one of molybdenum (Mo), molybdenum titanium (MoTi), vanadium (V), niobium (Nb), tantalum (Ta), hafnium (Hf), zirconium (Zr), titanium (Ti), cerium (Ce), lanthanum (La), yttrium (Y), scandium (Sc), or lithium (Li).

17. The display apparatus of claim 16, further comprising an organic layer disposed on the pixel electrode,
wherein a distance from an upper surface of the first coating layer to the organic layer is smaller than a thickness of the pixel electrode.

18. The display apparatus of claim 15, further comprising a plurality of color filters disposed between the substrate and the first metal structure,
wherein the plurality of color filters comprise a first color filter and a second color filter overlapping the pixel electrode,
wherein one end of the second color filter overlaps the first metal structure,
wherein another end of the second color filter overlaps the second metal structure, and
wherein a distance from a lower surface of the first metal structure to the plurality of color filters is smaller than a thickness of the pixel electrode.

19. The display apparatus of claim 16, further comprising:
a plurality of organic light-emitting layers disposed on the pixel electrode; and
a common electrode disposed to cover the plurality of organic light-emitting layers,
wherein a distance from an upper surface of the first coating layer to the common electrode is smaller than a thickness of the pixel electrode.

20. The display apparatus of claim 19, wherein the plurality of organic light-emitting layers comprise a first organic light-emitting layer and a second organic light-emitting layer disposed apart from the first organic light-emitting layer, and
wherein the first metal structure overlaps a region where the first organic light-emitting layer and the second organic light-emitting layer are spaced apart from each other.
